(19) United States
(12) Patent Application Publication
(10) Pub. No.: US 2023/0260489 A1
(43) Pub. Date: Aug. 17, 2023

(54) HARMONIC-BASED INTENSITY REGULATION SYSTEM, METHOD AND DEVICE FOR SOUND ASSETS

(71) Applicant: Mighty V. Bornfreedom, Brooklyn, NY (US)

(72) Inventor: Mighty V. Bornfreedom, Brooklyn, NY (US)

(21) Appl. No.: 18/110,864

(22) Filed: Feb. 16, 2023

Related U.S. Application Data
(60) Provisional application No. 63/311,436, filed on Feb. 17, 2022.

(51) Int. Cl. G10H 1/14; G10H 1/00

(52) U.S. Cl. CPC G10H 1/14; G10H 1/0008; G10H 2210/031; G10H 2210/315

(57) ABSTRACT

A harmonic-based intensity regulation system, method and device, disclosed herein, is applicable to sound assets. The system, in an embodiment, includes one or more data storage devices or tangible mediums that store or include a plurality of computer readable instructions configured to direct one or more processors to receive one or more inputs. The one or more inputs correspond to: a selection of one of a plurality of different harmonic classes, wherein each of the harmonic classes is associated with a variable harmonic frequency; a frequency range that is dimensioned or otherwise great enough to bound the variable harmonic frequency of the selected harmonic class and a plurality of other frequencies; an intensity threshold; and an amount of an intensity change. The instructions are also configured to direct the one or more processors to detect whether one or more frequencies of a frequency spectrum satisfy a regulation condition. The regulation condition includes a first requirement for the one or more frequencies to be within the frequency range, and the regulation condition also includes a second requirement for the one or more frequencies to have a designated relationship with the intensity threshold. The instructions are configured to direct the one or more processors to change an intensity of the detected one or more frequencies by at least part of the amount. The change can include an intensity decrease, an intensity elimination or an intensity increase.

### CROSS-REFERENCE TO RELATED APPLICATION

This application is a non-provisional of, and claims the benefit and priority of, U.S. Provisional Patent Application No. 63/311,436 filed on Feb. 17, 2022. The entire contents of such application are hereby incorporated herein by reference.

### COPYRIGHT NOTICE

A portion of the disclosure of this patent document contains material which is subject to copyright protection. The copyright owner has no objection to the facsimile reproduction by anyone of the patent disclosure, as it appears in the Patent and Trademark Office patent files or records, but otherwise reserves all copyright rights whatsoever.

### BACKGROUND

There are variety of known tools for music production and audio processing, including hardware and software. The known tools include digital audio workstations (DAWs) and software programs, among other equipment. DAWs are available in a variety of configurations, such as a standalone device, an assembly of interconnected devices (including equalizers) or a software program (or set of software programs) operable to run on a laptop computer. DAWs often incorporate or are operable with software programs commonly referred to as plugins. Plugins can extend the features and functionality of DAWs. Most DAWs have a central interface that allows the user to alter and mix multiple recordings and tracks into a final produced piece. DAWs can be used for producing and recording music (including songs), speech, sound effects and other media requiring audio recording and processing.

In advanced music production, the mixing and mastering processes can be meticulous, requiring the analysis, adjustment and fine tuning of a large array of settings and sound characteristics. There is a known software tool that performs dynamic equalization and multiband compression. This tool is operable to reduce or attenuate loudness or intensity. In the setup, the user inputs settings to specify a frequency range and an intensity reduction amount or attenuation amount (e.g., 3 dB). After that, the tool attenuates all of the frequencies in the range by the same attenuation amount for the entire duration of the musical piece that is being produced. This rigid attenuation process, therefore, does not adjust the attenuation level to variations (e.g., changes in vocal characteristics) that might occur during the musical piece.

One disadvantage of this known tool is lack of flexibility. Once the user specifies the frequency range and intensity reduction setting, this tool rigidly treats all frequencies within the range the same for the entire musical piece. This can result in undesirable music quality because this tool's rigid attenuation process fails to adjust to or account for variations that can occur in the musical piece, such as changes in vocal characteristic throughout the singer's performance.

This lack of flexibility can be particularly problematic with respect to the harmonics of a sound. For example, a certain tone or character of a sound may be associated with a specific harmonic. This harmonic may occur at several different frequencies throughout a singer's performance. This complexity can make it difficult for the engineer to manage that tone or character if the tone or character falls outside of the preset frequency range during the performance.

Furthermore, the tool's rigid attenuation process can affect the sound in unintended and undesirable ways by reducing the intensity of more frequencies than necessary to control a specific tonal or harmonic event. For example, the engineer may intend to use attenuation to control a nasal resonance in a vocal that is generally found around 1 kHz, but more specifically found at the 5th harmonic. In the set-up of the tool, the engineering may specify a frequency range that surrounds 1 kHz. However, during the performance, the singer may switch registers, singing an octave higher, causing the harmonic associated with the nasality to be found at 2 kHz. This can result in two problems. First, any reduction that occurs within the range that the engineer originally set will not address the nasal issue, but, instead, can reduce and disturb the intensity of desirable frequencies. Second, the reduction will not reduce the occurrences of the nasal tone at 2 KHz because the tone occurs outside of the range that the engineer originally set. Hence, the integrity of the signal can be compromised if the goal of the engineer was solely to manage the resonant tone while leaving other parts of the vocal unaffected.

Another known tool enables the user to identify a particular harmonic and apply a fixed intensity reduction that is specifically linked to the identified harmonic. This tool implements a method commonly referred to as pitch-tracking equalization. This tool reduces the intensity of the identified harmonic by a fixed (i.e., static) amount, such as 3 dB. Among other drawbacks, this approach does not take into account the dynamic component of the identified harmonic. For example, the identified harmonic can occur at various intensities during a music recording. The freedom of the intensity to naturally vary can provide the music with a desired quality, liveliness, and sound color. However, this known tool lacks such freedom by rigidly reducing the identified harmonic (and all of its intensities) by the same, fixed amount at all times. Consequently, the produced music can sound heavily altered, lacking in sound color and richness.

Furthermore, the known plugins have shortcomings in assisting users with controlling the frequency information of a digital audio sample (DAS). A DAS includes a data file that contains machine readable digits (e.g., numbers) that represent audio. DASs are readable or playable as audio through a digital-to-analog conversion (DAC) process. As a result of this additional shortcoming, users must spend relatively large amounts of time manually controlling DAS frequencies. Some users, because of time limitations, produce music having undesirable sounds or deficiencies in sound quality, color or richness.

The foregoing background describes some, but not necessarily all, of the problems, disadvantages and shortcomings related to music production and audio processing.

### SUMMARY

The intensity regulation system, method and device is operable to perform intensity regulation for sound assets. The intensity regulation system, in an embodiment, includes a multi-prong regulation condition operable with harmonic tracking or latching to cause an intensity change (e.g., reduction or increase, depending on the embodiment) for the frequency band that is the subject of modification, enhancement, improvement or correction. The intensity change occurs dynamically depending on shifts in frequency or pitch and also occurs in real time, for example, before the frequency band has been fully processed.

In an embodiment, the intensity regulation system provides the user with more control over pinpointing and selecting the harmonic partials in comparison to the conventional audio engineering technology. For the heightened level of user control, the intensity regulation system enables the user to select a specific harmonic frequency and control the level of that harmonic frequency separate from the level of other harmonic frequencies. This heightened level of control enables the user to conduct surgical changes (e.g., attenuation or boosting, depending on the embodiment), or correct the level of offensive frequencies of a given harmonic without affecting those nearby. The result is an enhancement of the overall tone or character of the audio signal, avoiding or minimizing compounding tonal changes that are undesirable or untrue to the source.

In addition, the intensity regulation system is operable to dynamically perform the intensity change. In one example of the dynamic change, the level of the original signal at a given harmonic frequency may be lowered or raised over time throughout the audio recording according to a designated mathematical model. Through dynamic reduction or increasing, the intensity regulation system is operable to trigger or kick-in the intensity change (e.g., reduction or boosting, depending on the embodiment) only when a qualifying sonic event occurs. This is contrary to the conventional methods that alter the tone or character of the signal in its entirety throughout the entire recording.

In an embodiment, the intensity regulation system includes one or more data storage devices, which have or store a plurality of computer readable instructions. The instructions are configured to direct one or more processors to receive a harmonic class input corresponding to a selection of one of a plurality of different harmonic classes. Each of the harmonic classes is associated with a variable harmonic frequency. The instructions are also configured to direct the one or more processors to receive a frequency range input associated with the selected harmonic class. The frequency range input specifies a frequency range that is great enough to bound the variable harmonic frequency of the selected harmonic class and a plurality of other frequencies. The instructions are also configured to direct the one or more processors to receive an intensity threshold input associated with the selected harmonic class. The intensity threshold input corresponds to an intensity threshold. The instructions are also configured to direct the one or more processors to receive an intensity change input associated with the selected harmonic class. The intensity change input corresponds to an amount of an intensity change. Depending on the embodiment, the intensity change includes either an intensity reduction, an intensity elimination, or an intensity increase. The instructions are also configured to direct the one or more processors to detect whether one or more frequencies of a frequency spectrum satisfy a regulation condition. The regulation condition includes a first requirement for the one or more frequencies to be within the frequency range, and the regulation condition also includes a second requirement for the one or more frequencies to have a designated relationship with the intensity threshold. The instructions are also configured to direct the one or more processors to change an intensity of the detected one or more frequencies by at least part of the amount. The frequency spectrum is based on a monophonic sound asset. The intensity change occurs before reaching an end of the frequency spectrum. Each of the variable harmonic frequencies is variable based on a change in a fundamental frequency. The harmonic frequency and the other frequencies within the frequency range are unmodified by any change in intensity unless the regulation condition is satisfied. In one embodiment, the designated relationship is that the one or more frequencies are greater than (or have risen to a point that is greater than) the intensity threshold. In another embodiment, the designated relationship is that the one or more frequencies are less than (or have fallen to a point that is less) the intensity threshold.

In another embodiment, one or more data storage devices store or include a plurality of computer readable instructions configured to direct one or more processors to receive one or more inputs. The one or more inputs correspond to a selection of one of a plurality of different harmonic classes. Each of the harmonic classes is associated with a variable harmonic frequency. The one or more inputs also correspond to a frequency range that is great enough to bound the variable harmonic frequency of the selected harmonic class and a plurality of other frequencies. The one or more inputs also correspond to an intensity threshold and an amount of an intensity change. The computer readable instructions are configured to direct one or more processors to detect whether one or more frequencies of a frequency spectrum satisfy a regulation condition. The regulation condition includes a first requirement for the one or more frequencies to be within the frequency range. The regulation condition also includes a second requirement for the one or more frequencies to reach or have a designated relationship with the intensity threshold. The computer readable instructions are configured to direct one or more processors to change an intensity of the detected one or more frequencies by at least part of the amount.

In an embodiment, a method for configuring an intensity regulation system includes configuring a plurality of computer readable instructions to direct one or more processors to receive one or more inputs. The one or more inputs correspond to a selection of one of a plurality of different harmonic classes. Each of the harmonic classes is associated with a variable harmonic frequency. The one or more inputs correspond also to a frequency range that is great enough to bound the variable harmonic frequency of the selected harmonic class and a plurality of other frequencies. Also, the one or more inputs correspond to an intensity threshold and an amount of intensity change. The method includes configuring the computer readable instructions to detect whether one or more frequencies of a frequency spectrum satisfy a regulation condition. The regulation condition includes a first requirement for the one or more frequencies to be within the frequency range. The regulation condition also includes a second requirement for the one or more frequencies to reach or have a designated relationship with the intensity threshold. The method includes configuring the computer readable instructions to change an intensity of the detected one or more frequencies by at least part of the amount.

In an embodiment, the frequency spectrum is associated with the DAS of a monophonic audio signal related to a sound asset, and this method includes configuring the computer readable instructions to direct the one or more processors to programmatically track the selected harmonic class while the one or more processors process the monophonic audio signal. During the tracking, the variable harmonic frequency is variable due to a change in fundamental frequency caused by pitch variation in a sound asset related to the monophonic audio signal.

Additional features and advantages of the present disclosure are described in, and will be apparent from, the following Brief Description of the Drawings and Detailed Description.

### BRIEF DESCRIPTION OF THE DRAWINGS

FIG. 1 is a diagram illustrating an example of sound wave and the components thereof.

FIG. 2 is a diagram illustrating another example of a sound wave plotted on a graph having an X time axis and a Y amplitude axis.

FIG. 3 is a diagram illustrating examples of several sound waves that correspond to different intensities and different pitches.

FIG. 4 is a diagram illustrating an example of a plurality of sound waves and a complex sound wave.

FIG. 5 is a diagram illustrating an example of a sound wave series.

FIG. 6 is a diagram illustrating an example of a plurality of harmonic classes.

FIG. 7 is a diagram illustrating an example of the cycles of a sound wave.

FIG. 8 is a diagram illustrating an example of a frequency spectrum, a selected frequency band and a bandwidth.

FIG. 9 is a diagram illustrating an embodiment of an electronic configuration in which the DAW includes the intensity regulation system.

FIG. 10 is a diagram illustrating an embodiment of an electronic configuration in which the intensity regulation system is functionally or operatively coupled to the DAW.

FIG. 11 is a diagram illustrating an embodiment of the DAW interface.

FIG. 12 is a diagram illustrating an embodiment of the system interface.

FIG. 13 is a diagram illustrating an example of a frequency spectrum, a frequency range, a frequency spectrum, and a smoothing curve.

FIG. 14 is a top view of an embodiment of the system interface, showing an example of harmonic class selection, wherein the user selected the first harmonic (fundamental frequency).

FIG. 15 is a top view of an embodiment of the system interface, showing an example of harmonic class selection, wherein the user selected the second harmonic.

FIG. 16 is a top view of an embodiment of the system interface, showing an example of the user's setting of a desired frequency range.

FIG. 17 is a top view of an embodiment of the system interface, showing an example of the user's setting of a desired frequency range.

FIG. 18 is a top view of an embodiment of the system interface, showing an example of the user's setting of a desired intensity reduction amount, through use of the reduction amount section.

FIG. 19 is a top view of an embodiment of the system interface, showing an example of the user's setting of a desired intensity reduction amount, through use of the reduction amount section.

FIG. 20 is a top view of an embodiment of the system interface, showing an example of the user's setting of a desired intensity threshold, through use of the threshold section.

FIG. 21 is a top view of an embodiment of the system interface, showing an example of the user's setting of a desired intensity threshold, through use of the threshold section.

FIG. 22 is a diagram illustrating the structure, logic and operation of an embodiment of the multi-prong regulation condition.

FIG. 23 is a diagram illustrating the structure, logic and operation of an embodiment of the second prong of the regulation condition that has a designated relationship that is specified for intensity reduction or attenuation.

FIG. 24 is a diagram illustrating the structure, logic and operation of an embodiment of the second prong of the regulation condition that has a designated relationship that is specified for intensity increase or boost.

### DETAILED DESCRIPTION

Throughout this disclosure set forth herein, the word “including” indicates or means “including, without limitation,” the word “includes” indicates or means “includes, without limitation,” the phrases “such as” and “e.g.” indicate or mean “including, without limitation,” and the phrase “for example” refers to a non-limiting example.

1. Sound and Music Principles

1.1 Sound Waves

A sound, such as a hum of one's voice propagates as a signal. The signal travels through a medium like water or air as energy, causing air pressure to rise and fall at a given rate. The rise-and-fall of the air pressure can be modeled as a sine wave or a sum of sine waves defined by attributes including wavelength, period, amplitude and frequency. For simplicity, these attributes can be considered attributes of a sound wave.

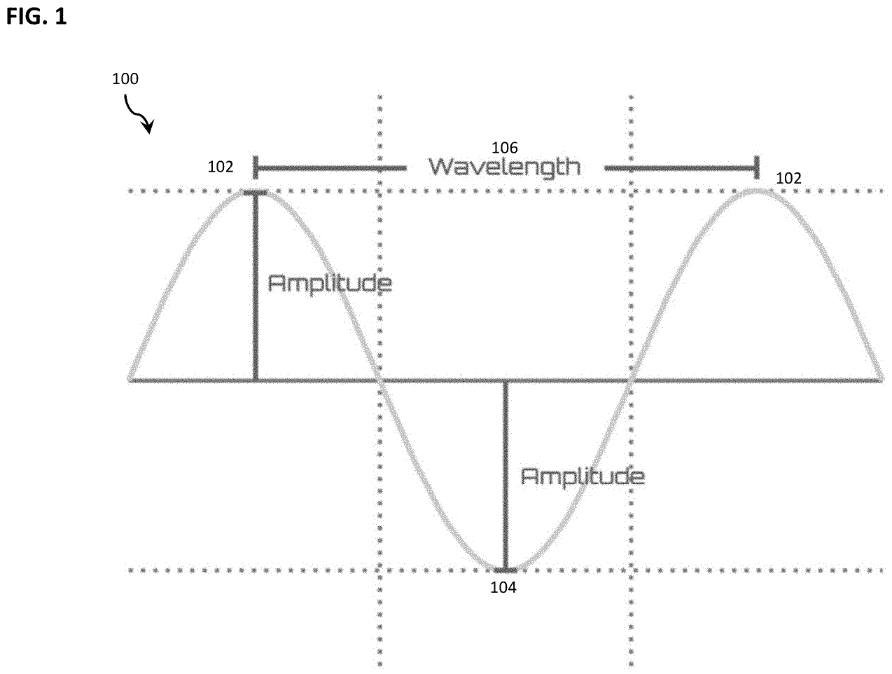

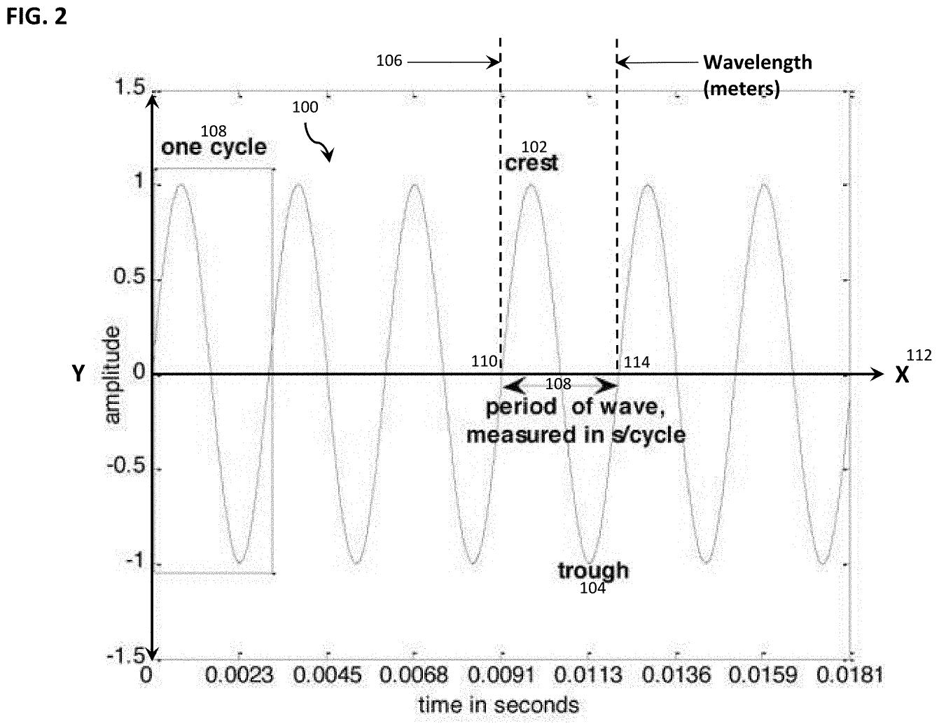

In the example shown in FIGS. 1-2, the sound wave 100 has a peak or crest 102 and a valley or trough 104. The wavelength 106 of the sound wave 100 is the length (measurable in meters or another dimension) from the start to the end of one full cycle 108 of the waveform. For example, the wavelength 106 extends from the sound wave's intersection 110 with the centerline 112 (e.g., X-axis) to the sound wave's immediate, next intersection 114 with the centerline 112. The period of the sound wave 100 is calculated as the time required for the completion of one full cycle 108 of the sound wave 100.

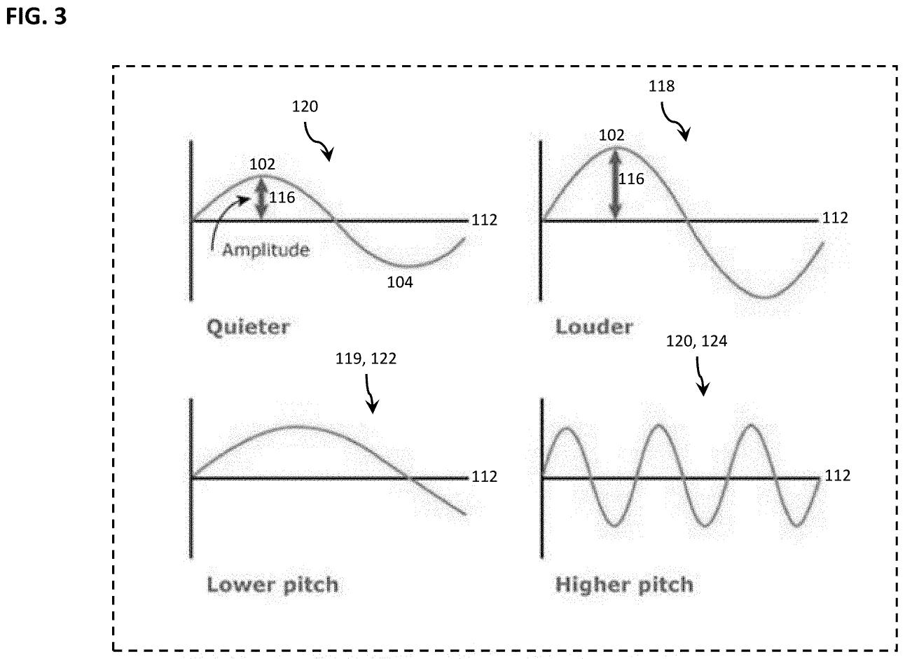

Referring to FIGS. 1-3, the amplitude 116 of the sound wave 100 is the maximum displacement of the sound wave 100 from the centerline 112 to the crest 102, not the vertical distance from crest 102 to trough 104. The greater the distance from the centerline 112, the more intense the pressure variation will be within a medium, resulting in a louder perception of sound, as shown by sound wave 118 in FIG. 3. On the other hand, the lesser the distance from the centerline 112, the quieter perception of sound, as shown by sound wave 120 in FIG. 3. A decibel (db) is a scientific unit that measures the intensity or loudness of a sound. The softest sound that a human can hear is the zero point. Humans speak normally at about 60 decibels.

Frequency is calculated as the quantity of full cycles 108 that pass any particular point on the centerline 112 per second. The frequency indicates the rate of pressure variations caused by the moving object that generates the sound. In the examples shown in FIG. 3, the sound wave 119 has a longer wavelength than the sound wave 120. Longer wavelengths result in lower frequency, and shorter wavelengths result in higher frequency. As described below, pitch is based on the frequency of the sound wave.

The frequency of a sound wave is measured in hertz (Hz). The frequency range in which humans can hear is 20 Hz to 20,000 Hz and is called the audible range or the audible spectrum. If a singer's diaphragm vibrates back and forth at a frequency of 900 Hz, then the diaphragm generates 900 condensations per second, resulting in a sound wave whose frequency is 900 Hz.

Pitch is the human perception of sound as being high, low or somewhere between high and low. Pitch depends on the frequency of the sound wave. In other words, the frequency of a sound wave determines the pitch, the perception of whether the sound is relatively high (e.g., the sound of a sports whistle) or relatively low (e.g., the sound of a foghorn or tuba instrument). In music parlance, the terms “pitch” and “frequency” are sometimes used interchangeably. For example, the C note on a regular piano may be described as having pitches ranging from 32.70 Hz to 4186.01 Hz. A relatively low frequency 122, as shown in FIG. 3, results in a relatively low pitch, and a relatively high frequency 124, as shown in FIG. 3, results in a relatively high pitch.

The raising or lowering of the pitch over a period of time may be referred as the shifting of the pitch. For example, in lyrics “ . . . I will be . . . ,” a vocalist may sing the word, “be” in a chain, be-eeee-eeeeeeee, for three continuous seconds with three different pitches: be (high pitch), eeee (moderate pitch) and eeeeeeee (low pitch). While singing this word in real time, the vocalist's pitch shifts from high to moderate to low. During the real time shifting of this pitch, the intensity regulation system 210, as described below, is operable to track (and programmatically latch onto) the pitch and regulate the associated intensity for purposes of improving or alerting the sound quality.

The velocity is the speed and direction of a sound wave. Sound waves travel at different speeds through different mediums. Through the air, sound travels at 344 meters per second. Generally speaking, the denser the medium, the faster sound travels through it.

1.2 Monophonic Sounds

Sound can be generated by one or more moveable objects or air movers, such as one or more vocalists in a performance or recording session. In some cases, sound can be generated by a single air mover, such as a single vocalists or a single instrument. The term monophonic sound can be used to describe such a case in which a sound (and the associated DAS) is generated by a single object, such as the vocal of a single singer or notes of a single piano. In contrast, the term polyphonic sound can be used to describe sounds (and the associated DASs) generated by multiple air movers, such as the vocals of three singers, or the notes of a piano, trumpet and tuba played simultaneously.

In one example, a studio session may include two singers and a soundtrack having instrumentals and a beat based on a repeating clap. The studio's DAW may include three audio channels, a first channel for the microphone of one singer, a second channel for the microphone of the other singer, and a third channel for playing the soundtrack. During the session, the two singers hear the soundtrack, and their vocals are separately recorded on the two audio channels as DASs. After the session, the engineer can playback, analyze and optimize the audio recording of one singer, and the engineer can separately do the same for the audio recording of the other singer. Each audio recording is considered a monophonic sound because the recording is that of a single air mover, in this example, a single singer. The terms, sound generator, air mover, sound source and performer may be used interchangeably to describe any object, substance or form of matter (animate or inanimate) whose movement or activity, causes the output or production of sound, including a vocalist, musical instrument and other things.

1.3 Sequential Sounds Waves of a Monophonic Sound

A monophonic sound can include a chronological or sequential chain of sound segments that have different pitches, each of which is based on a unique frequency. Continuing with the example provided above, the audio recording of a single one of the singers may include the word, “see” sung for a relatively long amount of time with a varying pitch, such as see-seeee-seeeeee. In this example, the first segment (see) has a relatively high pitch, the second segment (seeee) has a moderate pitch, and the third segment (seeeeee) has a relatively low pitch. Accordingly, the entire audio segment or band for see-seeee-seeeeee may, for example, have the following pitches occurring in sequence at the following time points:

TABLE A

| | Part of the | | | |
|---|---|---|---|---|
| Time Axis | Audio Segment | | | |
| (Min. and Sec.) | (Band) | Note | Pitch | Frequency |
| 0.7 to 1.3 | First | C, octave 6 | High | 1,000 Hz |
| 1.3 to 2.8 | Second | B, octave 4 | Moderate | 500 Hz |
| 2.8 to 4.6 | Third | B, octave 3 | Low | 250 Hz |

As illustrated above, each segment of the “see” sound has its own unique pitch and frequency. This demonstrates how a monophonic recording can have a continuous, sequential chain of monophonic sound components that vary over a period of time. The monophonic sound components can have different sound waves, each of which has a different frequency corresponding to a different pitch.

Another example is the song, I Will Always Love You by Whitney Houston. Whitney's vocals, excluding the instrumentals, result in a monophonic sound (and associated DAS) of her voice. This song includes the looped lyrics, “ . . . and I will always love you . . . .” Whitney holds her vocal for the word “you” for a relatively long time. Depending on the part of the song, the duration of the “you” vocal varies from about 1.5 seconds to about 12 seconds. The last word of the song is “you,” which is continuously sounded with a duration of about 12 seconds in which Whitney gradually raises the pitch. The varying pitch can be described as youuu-ouuuuuu-ouuuuuuuuu, wherein the first segment (youuu) has a relatively low pitch, the second segment (ouuuuuu) has a moderate pitch, and the third segment (ouuuuuuuuu) has a relatively high pitch. In this example, these three segments occur in a sequential, continuous chain. Accordingly, the entire audio segment or band for “you” may, for example, have the following pitches occurring in sequence at the following time points:

TABLE B

| Time Axis | Part of the Audio Segment | | |
|---|---|---|---|
| (Min. and Sec.) | (Band) | Pitch | Frequency |
| 4.20 to 4.26 | First | Low | 200 Hz |
| 4.26 to 4.30 | Second | Moderate | 500 Hz |
| 4.30 to 4.34 | Third | High | 900 Hz |

1.4 Composite Sound Waves of a Monophonic Sound

In many cases, each part or segment of a monophonic sound is the result of multiple sound waves that form a composite sound wave. A plurality of simple sound waves overlap, occurring simultaneously, as opposed to sequentially. A composite or complex sound wave, also referred to as a complex waveform, is typical in naturally occurring sounds, such as sounds generated by vocals and instruments. Though uncommon, a monophonic sound can be the result of a single sound wave—a single sine wave generating a pure tone, as described below.

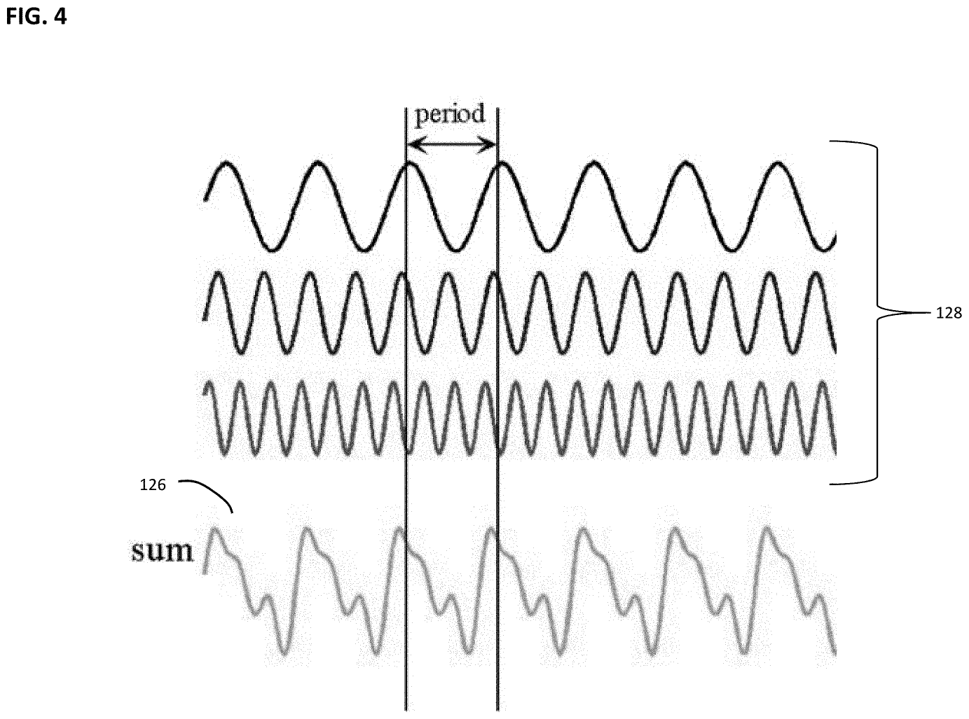

In the example shown in FIG. 4, a composite or complex sound wave 126 includes, is constructed of or is based on a plurality of sound waves 128. The complex sound wave 126 can be decomposed into the sound waves 128. Referring to the song, I Will Always Love You, described above, a single segment of the youuu-ouuuuuu-ouuuuuuuuu sound is the result of multiple sound waves that form a composite or complex sound wave. This is because this sound comes from Whitney's voice, naturally occurring.

1.5 Polyphonic Sound

A polyphonic sound (and the associated DAS) is the result of capturing or combining multiple sound waves simultaneously produced by multiple sound generators. Each sound generator (e.g., singer) produces a sound with its own sound wave, simple or composite. A polyphonic sound can be the result of the vocals of two singers singing simultaneously or a singer and an instrument simultaneously generating sounds. The DAS corresponding to the polyphonic sound can include or represent a plurality or combination of complex and simple sound waves.

1.6 Harmonic Sound

Sounds can be characterized as having a fundamental frequency, a plurality of harmonics and a plurality of overtones. The lowest harmonic frequency associated with the pitch of a sound is known as the fundamental frequency or simply, the fundamental. The fundamental frequency provides the sound with its strongest, audible pitch or pitch reference. The voiced speech of a typical adult male has a fundamental frequency from 85 Hz to 155 Hz, and that of a typical adult female has a fundamental frequency from 165 Hz to 255 Hz.

Sound generators, such as a vocalist, can change the fundamental frequency produced by their vocal cords throughout a performance or recording session. For example, throughout a song, a vocalist can generate sound at different fundamental frequencies. Referring, again, to the Whitney Houston example described above, Whitney changed the fundamental frequency when raising the pitch within the chain of the sound, youuu-ouuuuuu-ouuuuuuuuu. The first segment of the sound (youuu) has a relatively low fundamental frequency corresponding to a relatively low pitch, the second segment of the sound (ouuuuuu) has a moderate fundamental frequency corresponding to a moderate pitch, and third segment of the sound (ouuuuuuuuu) has a relatively high fundamental frequency corresponding to a relatively high pitch.

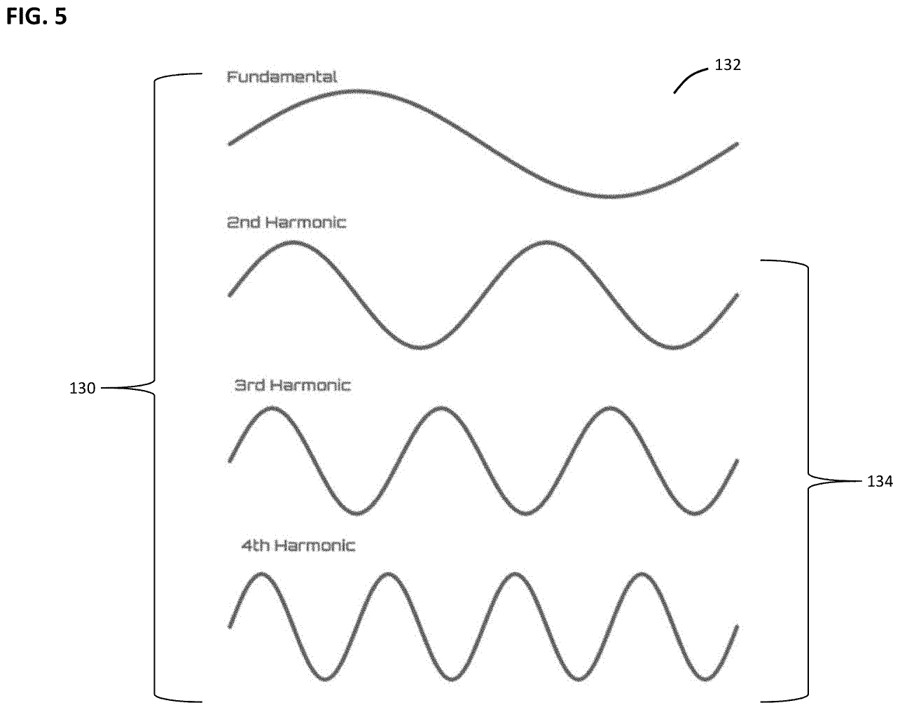

The composite or complex sound wave of a monophonic sound includes a fundamental sound wave having a fundamental frequency as well as a plurality of related sound waves. In the example shown in FIG. 5, a sound is the result of a sound wave series 130. The sound wave series 130 includes a fundamental sound wave 132 (having a fundamental frequency) and a plurality of ancillary sound waves 134 related to the fundamental sound wave 132. The ancillary sound waves 134 can be variations of the fundamental sound wave 132. For example, if the frequency of the fundamental sound wave is 400 Hz, the frequency of one of the ancillary sound waves could be any multiple of 400 Hz, such as the product of 400 Hz and the value of 0.3, 0.7, 1.4 or 2.

Some of the ancillary sound waves of a composite or complex sound wave can have a frequency that is an integer multiple of the fundamental frequency. For example, if the frequency of the fundamental sound wave is 400 Hz, the frequency of one of the ancillary sound waves could be any integer multiple of 400 Hz, such as the product of 400 Hz and an integer (e.g., whole number), such as 2, 3, 4, 7, 10, 13, 16 or 20. In this case, such an ancillary sound wave may be referred to as a partial or harmonic.

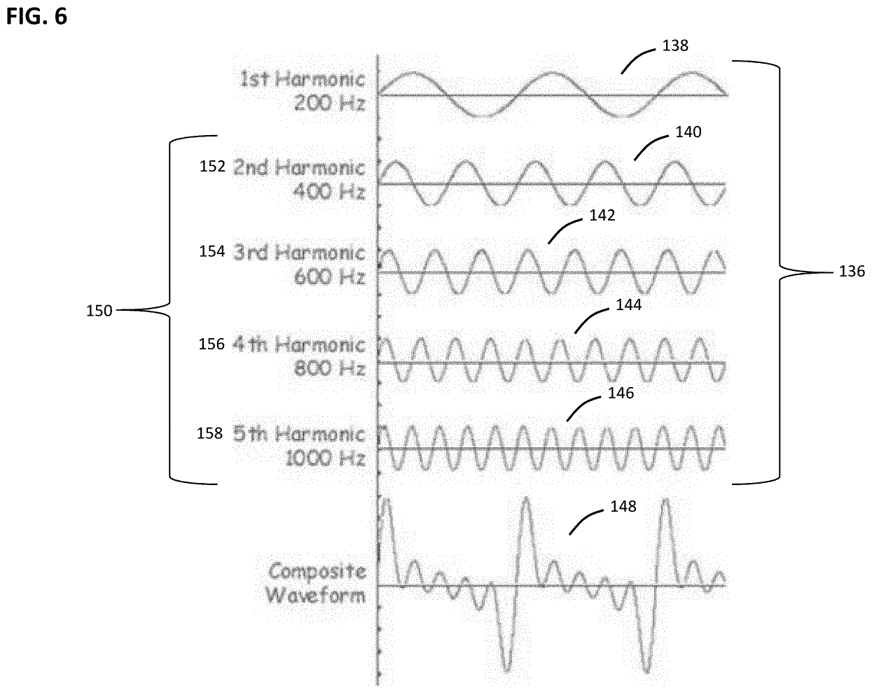

As shown in FIG. 6, the harmonic series 136 includes a fundamental sound wave (first harmonic sound wave) 138, a second harmonic sound wave 140, a third harmonic sound wave 142, a fourth harmonic sound wave 144, and a fifth harmonic sound wave 146. As shown in this example, the frequency increases when progressing in the harmonic series 136 from the fundamental sound wave 138 to the second harmonic sound wave 140, from the second harmonic sound wave 140 to the third harmonic sound wave 142, from the third harmonic sound wave 142 to the fourth harmonic sound wave 144, and from the fourth harmonic sound wave 144 to the fifth harmonic sound wave 146. As shown in FIG. 6, the frequency of each such harmonic sound wave is an integer (e.g., a whole number) multiple of the 200 Hz frequency of the fundamental sound wave 138. In this example, the variable fundamental frequency is the first harmonic in the series. Although the second, third and fourth harmonic classes are shown, it should be appreciated that there are additional harmonic classes, such as fifth, sixth, etc.

As shown in FIG. 6, the harmonic series 136 has a plurality or series of harmonic orders, rankings, ranks, levels, positions, categories, bins or classes 150, including harmonic classes 152, 154, 156, 158. Each of the harmonic classes 150 is associated with an integer multiplier (e.g., 2, 3, 4, etc.). The relationship among the harmonic classes 150 depends on the differences between the values of such integer multipliers.

The harmonic series 136 results in a composite or complex sound wave 148. It should be appreciated that harmonics can be present even though it can be difficult to distinctly perceive them as single components. In an embodiment, the composite or complex sound wave 148 is constructed of, and can be decomposed into, its components—the fundamental sound wave (first harmonic sound wave) 138, the second harmonic sound wave 140, the third harmonic sound wave 142, the fourth harmonic sound wave 144, and the fifth harmonic sound wave 146.

As Illustrated in the Example Shown in the Following Table C, a Harmonic Series Includes a Plurality of Sequential Harmonic Classes:

TABLE C

| Fundamental | | Frequency of |
|---|---|---|
| Frequency | Harmonic Class | Harmonic Partial |
| 50 Hz | 3^{rd} Harmonic (H3) | 150 Hz |
| 100 Hz | 3^{rd} Harmonic (H3) | 300 Hz |
| 200 Hz | 3^{rd} Harmonic (H3) | 600 Hz |

As shown in Table C, as the fundamental frequency increases, the frequency of the harmonic partial increases. In this example, the varying fundamental frequency is the first harmonic in the harmonic series. Continuing with this example, an audio recording can include a sound having a continuous sequence of sound segments. The sound can be based on a fundamental frequency that changes from 50 Hz (for a first sound segment) to 100 Hz (for a second sound segment) to 200 Hz (for a third sound segment). As shown, each such change causes a change in the frequencies of the harmonic partials.

It should be understood that the harmonic partials differ from harmonic class to harmonic class. For example, as shown in Table D, the fundamental frequency can remain constant for a sound, and the frequencies of the harmonic partials can differ based on the harmonic class, as follows:

TABLE D

| Fundamental | | Frequency of |
|---|---|---|
| Frequency | Harmonic Class | Harmonic Partial |
| 50 Hz | 2^{nd} Harmonic (H2) | 100 Hz |
| 50 Hz | 3^{rd} Harmonic (H3) | 150 Hz |
| 50 Hz | 4^{th} Harmonic (H4) | 200 Hz |

1.7 Overtones and Timbre

In some cases, a composite or complex sound wave has a fundamental sound wave and ancillary sound waves that are not directly related to the fundamental frequency. The sounds generated by these ancillary sound waves may be referred to as overtones. It should be understood that an audio recording from a studio session can include a combination of harmonics and overtones, which collectively affect the sound quality.

Two tones or sounds produced by different instruments might have the same fundamental frequency and thus the same pitch (e.g., a C note) but sound very different because of the presence of different amounts of harmonics and overtones within the composite sound wave. This can be referred to as the timbre. The timbre describes those characteristics of sound which enable the ear to distinguish sounds that have the same fundamental pitch. It is due to the timbre that people can distinguish one instrument from another. For example, a piano played at note C3 sounds differently from a guitar plucked at note C3.

1.8 Pure and Complex Tones

Pure tones or sounds are based on simple sine waves at a single frequency. A pure tone generator, including specialized hardware and software, can produce pure tones for purposes of audio analysis, optimization and engineering. No musical instrument (e.g., trumpet) or voice produces a pure tone. Most sounds generated by musical instruments and voices are based on a combination of harmonics and overtones, resulting in a complex tone. For example, if one plays an A note (440 Hz) on a violin, the complex tone produced by the violin may include sound at 440 Hz as well as simultaneously produced sound at 880 Hz, 1320 Hz, 1760 Hz, etc. The relative amplitudes of the different harmonics can determine the tone quality or timbre of the note.

Furthermore, the ancillary sound waves of a complex tone can include sound waves of non-harmonics. The complex tone (e.g., the sound of a note with a timbre particular to the instrument playing the note) can be described as a combination of many simple periodic sound waves or partials, each having its own set of wave characteristics, as described above.

1.9 Wave Phase and Interference

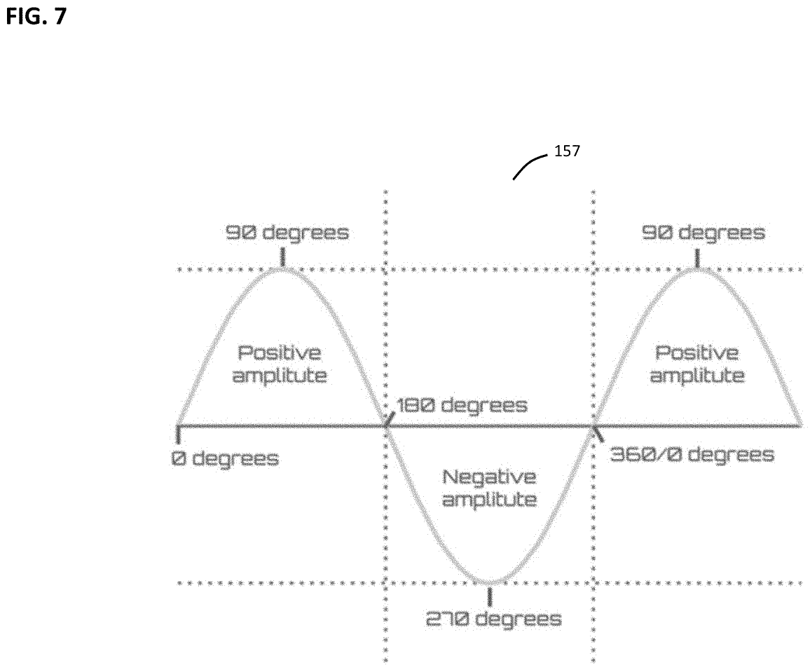

Sound waves occur in cycles; that is, they proceed through repetitions. Phase indicates how far along a sound wave has traveled in its current cycle. As shown in FIG. 7, the starting point of a sound wave 157 is 0 degrees, the peak of the sound wave 157 is 90 degrees, the next neutral pressure point is 180 degrees, the peak low-pressure zone is 270 degrees, and the pressure rises to zero again at 360 degrees.

As described above, a sound is typically the result of the sum of multiple, simultaneously occurring waves. If multiple sound waves are involved in producing a sound, their relative amplitudes often differ at any one point in time. If the sound waves are completely in phase they will combine to make a new waveform with the same frequency but double the amplitude. This is known as constructive interference. If the same two sound waves are combined while being completely out of phase by 180 degrees, they will cancel each other out resulting in no amplitude. This is known as destructive interference.

When two sound waves with the same frequency but different starting points combine, the resulting wave is said to have a phase shift. The new sound wave will still have the same frequency as the original sound wave but will have increased or decreased amplitude depending on the degree of phase difference.

Phase interferences are a common occurrence in the recording environment. Waves can often be heard to be in phase near a boundary (e.g., a wall of the recording room) when an incident wave combines with the reflective wave returning from the boundary. For example, if a microphone is positioned close to a wall, there can be roughly a doubling rise in amplitude in comparison to the microphone being positioned away from the wall. However, if the properties of the wall surface absorb or diffract the incident sound wave, the amplitude of the resulting wave will not be doubled.

One of the most common types of interference within a studio environment is phase shift. If, for example, two microphones pick up the same sound source (e.g., a trumpet sound) at different distances, there will effectively be a phase difference between the two waves. This is because it will take longer for the trumpet sound to arrive at the more distant microphone.

1.10 Band

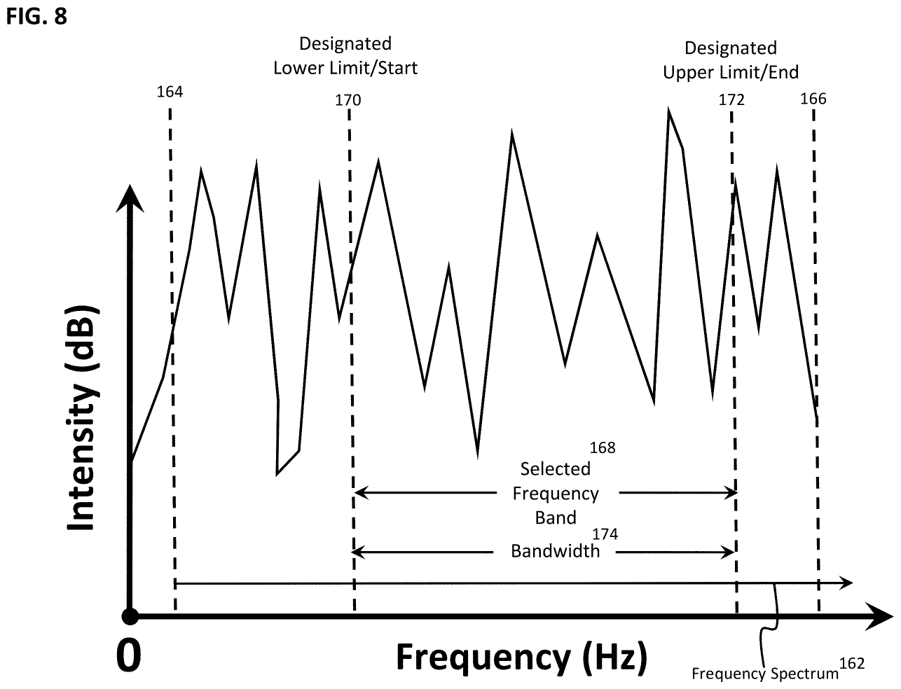

As shown in FIG. 8, the audio frequency spectrum 162 is the range of frequencies produced by a sound. When sound generators (such as a vocalist or instrument player) produce sound, the sound results in an audio signal. The frequency spectrum 162 of the audio signal spans from the lowest audible frequency of the sound (e.g., lowest frequency 164) of the audible sound to the highest audible frequency of the sound (e.g., highest frequency 166). An audio engineer may desire to analyze and modify a particular frequency segment, such as frequency band 168, that is located between the lowest and highest frequencies 164, 166. To do so, the engineer may identify and select the frequency band 168, as described below. A frequency band, such as frequency band 168, can be described as a continuous range of frequencies within the audio frequency spectrum 162 that are located between specified, selected or designated upper and lower limits 170, 172, respectively. Bandwidth 174 can be described as the difference between the designated upper and lower limits 170, 172. In the example shown, the frequency band 168 ranges from a designated lower limit 170 (e.g., 100 Hz) to a designated upper limit 172 (e.g., 350 Hz). In this example, the bandwidth 174 of the frequency band 168 is 250 Hz.

In music production and audio analysis, an engineer may receive a project based on a musical piece, an audio asset, or a sound asset that includes one or more audio recordings, each of which has an original playback length of 3 minutes. Each such audio recording can contain a single monophonic DAS. After review, the engineer may decide to modify, for example, one of the DASs by increasing or decreasing the intensity of a frequency band 168 associated with the DAS. In practice, the engineer can decide upon the values of the upper and lower limits of the desired frequency band 168, proceed to analyze the sound characteristics of such frequency band 168, and then change the intensity of that frequency band 168.

2. Intensity Regulation System, Method and Device

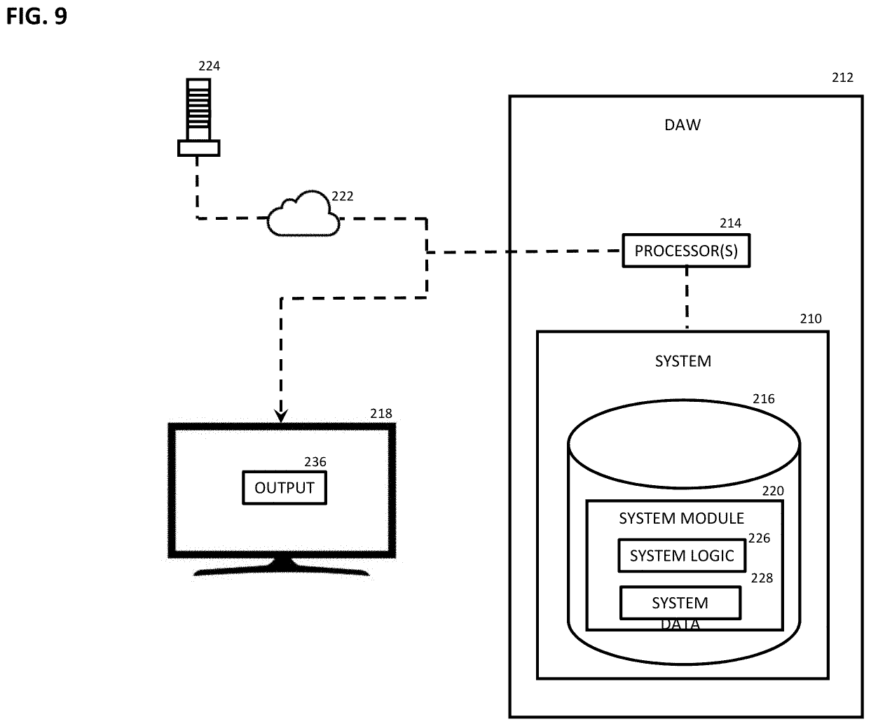

Referring to FIG. 9, in an embodiment, the intensity regulation system 210 is configured to be included within, incorporated into, nested within, functionally linked to, operatively coupled to or programmatically interfaced with any suitable DAW, such as DAW 212, which can include software, hardware or a combination thereof, such as one or more computers, workstations and laptops. In the embodiment shown, DAW 212 includes one or more data processors 214 as well as one or more data storage devices 216, such as hard drives, hard discs and memory chips.

DAW 212 includes a plurality of computer readable instructions and data. The computer readable instructions of the DAW 212 are configured to be executed by one or more processors to: (a) receive electronic audio signals corresponding to sound produced by sound generators, such as instruments and vocalists; (b) produce or generate one or more audio recordings in the form of one or more audio data files; and (c) store, process, modify and enhance the audio recordings. DAW 212 includes or is operatively coupled to one or more display devices, such as display device 218.

In an embodiment, the intensity regulation system 210 includes a system module 220 included within and stored on the one or more data storage devices 216. In an example, the system module 220 includes a plugin module that is operable with the DAW 212. For example, such plugin module is downloadable, over a data network 222 (e.g., the Internet), from a web server 224 to the one or more data storage devices 216. Once such plugin module is loaded onto the DAW 212, such plugin module is configured to add to the DAW 212, the functionality and capabilities of the intensity regulation system 210, as described below. In an embodiment, the plugin module includes a digital signal processing logic or circuitry configured to alter the sound of the audio signal related to the applicable sound asset.

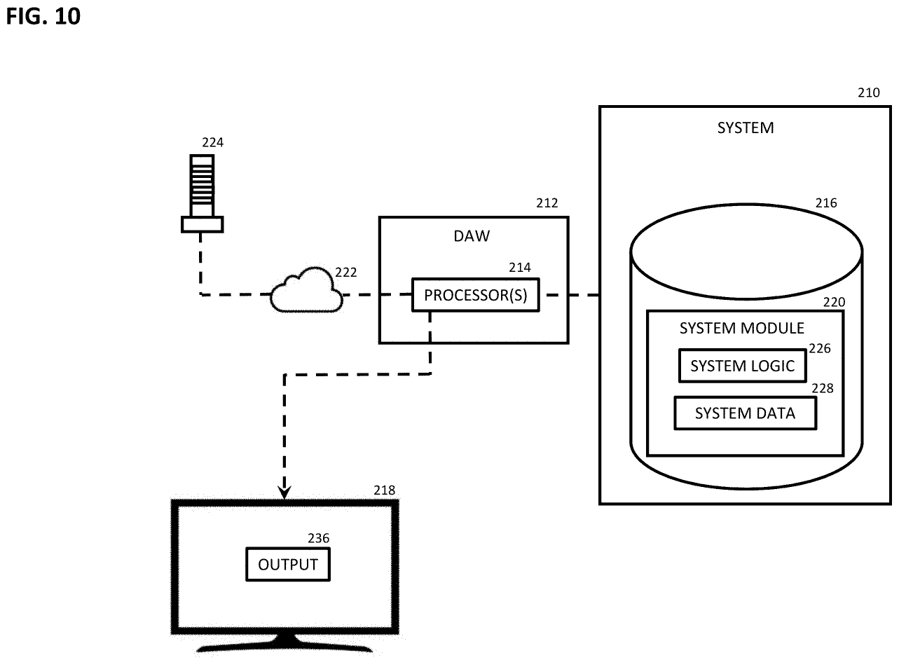

In another embodiment, the intensity regulation system 210 is operable as a standalone entity outside of DAWs. In the example shown in FIG. 10, the intensity regulation system 210 is includes the one or more data storage devices 216 that store the system module 220. As shown, the intensity regulation system 210 resides outside of the DAW 212 but is operatively coupled to the one or more data processors 214 of the DAW 212.

In each of the embodiments shown in FIGS. 9 and 10, the system module 220 includes system logic 226 and system data 228. In an embodiment, the system logic 226 includes or specifies a plurality of computer readable instructions that are structured, arranged, organized and configured to be executed by the one or more data processors 214. In an embodiment, the computer readable instructions are machine readable or otherwise executable by the one or more data processors 214. The computer readable instructions are configured to direct the one or more processors 214 to perform the functions of the intensity regulation system 210 described below. When directed by the computer readable instructions, the one or more processors 214 are programmed to perform such functions. At times herein, the intensity regulation system 210 may be described as performing the functions conducted by the one or more processors in accordance with the system logic 226.

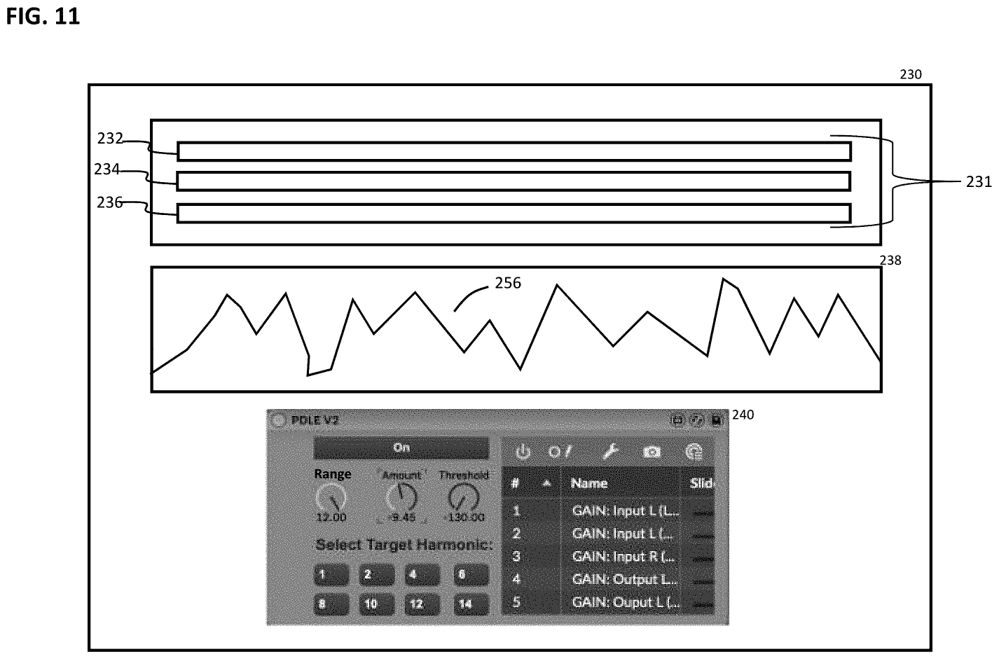

In the example shown in FIG. 11, DAW 212 is operable to generate a DAW interface 230, which is displayable by the display device 218, as shown in FIGS. 9-10. The DAW interface 230 displays a plurality of individually selectable sound tracks 231, including, in this example, sound tracks 232, 234, 236. Each of the sound tracks 231 can be considered a lane within the DAW 212 that stores an audio data file related to an audio asset or sound asset. Depending on the circumstance, an entire group of the sound tracks 231 can collectively correspond to a single audio asset or sound asset.

In an example, a user may use DAW 212 to record an audio asset or sound asset, such as a hip-hop song produced by one or more performers. DAW 212 converts the analog signal of the sound asset to a digital signal. In an embodiment, DAW 212 stores a data file derived from the data signal. The data file contains digital code and data that represent the sound asset.

In one example, the sound tracks 231 may include the monophonic vocals of a first vocalist on sound track 232, the monophonic vocals of a second vocalist on sound track 234, and a monophonic beat with a repeating clap on sound track 236. For each of the sound tracks 231, the one or more data storage devices 216 store a data file containing the digital code and data that represent the sound of such sound track 231.

DAW interface 230 also displays a frequency analyzer dashboard 238, which is displayed by the display device 218. The intensity regulation system 210 is operable to generate a system interface 240, which is displayed by the display device 218. In the embodiment shown, the system interface 240 is located within the DAW interface 230. However, in other embodiments, the system interface 240 is located outside of, but adjacent to, the DAW interface 230.

DAW 212 enables the user to select one of the sound tracks 231. In response, DAW 212 displays a frequency line 256 within the frequency analyzer dashboard 238. The frequency line 256 is plotted relative to a horizontal axis measuring frequency (Hz) and a vertical axis representing intensity (db). The frequency line 256 is continuous and can have peaks, valleys, straight segments and curved segments. The shape of the frequency line 256 represents variations in the frequency of the sound asset related to the selected sound track 231. When DAW 212 plays the sound asset, processing the associated data file, the frequency line 256 moves and changes shape based on, among other factors, variations in the pitch of the sound asset.

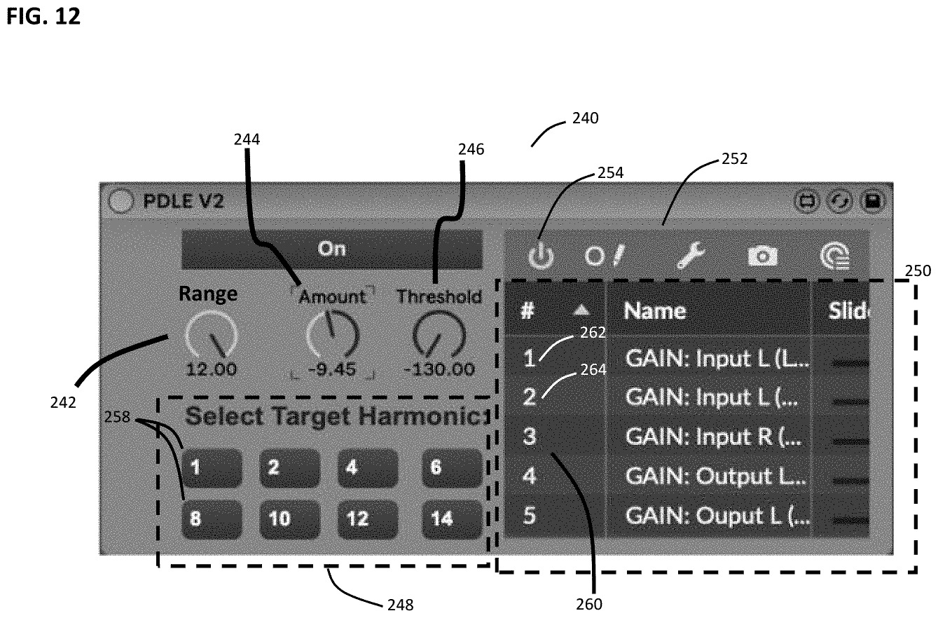

As shown in FIG. 12, in an embodiment, the system interface 240 includes a frequency range section 242, a reduction amount section 244, a threshold section 246, a harmonic class section 248, a setting section 250, and a plurality of control elements 252, including a mode control element 254. In response to the user's selection or activation of the frequency range section 242, the intensity regulation system 210 adjusts a graphical a dial, meter, gauge or other element that enables the user to select a desired frequency range. In the example shown, the frequency range section 242 displays a dial having a range parameter that is adjustable from a range parameter of 0.00 to 12.00. Each range parameter corresponds to a designated scope or range for frequency, such as a range sized to bound a bandwidth of 40 Hz, 100 Hz, 120 Hz, 380 Hz, 1,000 Hz, etc. For example, a range parameter of 1.0 may correspond to a range bandwidth of 100 Hz, and a range parameter of 9.00 may correspond to a range bandwidth of 900 Hz. As described below, the frequency range (in other words, a frequency basket, bin, scope, catch, lasso or net) is selected or specified by the user to enhance the user's control and results for improving or otherwise modifying the sound asset.

In response to the user's selection or activation of the reduction amount section 244, the intensity regulation system 210 adjusts a graphical dial, meter, gauge or other element that enables the user to input or select a desired amount of intensity (dB). In the example shown, the reduction amount section 244 displays a dial having an intensity reduction parameter that is adjustable from an intensity reduction parameter having a value of −0.00 to −20.00. Each intensity reduction parameter corresponds to a designated magnitude or amount of intensity reduction, such as an intensity reduction value of −10 dB, −12 dB, −18 dB, −50 dB, etc. In an embodiment, the system logic 226 includes one or more mathematical formulas, ratios (e.g., compression ratios) or algorithms that convert the convert the different intensity reduction parameters to different decibels.

For example, an intensity reduction parameter of −4.00 may correspond to an intensity reduction value of −20 dB, and an intensity reduction parameter of −8.00 may correspond to an intensity reduction value of −80 dB. As described below, each intensity reduction parameter server as an intensity cutout or cut-down, effectively lowering the intensities of one or more frequencies by the value of the intensity reduction selected or specified by the user.

In response to the user's selection or activation of the threshold section 246, the intensity regulation system 210 adjusts a graphical dial, meter, gauge or other element that enables the user to input or select a desired level of intensity, threshold of intensity or intensity threshold. In an embodiment, the intensity threshold is a decibel value. In an alternative embodiment, the intensity threshold is a threshold parameter that corresponds to a decibel value.

In the example shown, the threshold section 246 displays a dial having an intensity threshold parameter that is adjustable from an intensity threshold parameter of a value of −130.00 dB (a relatively low threshold) to a value of −20.00 db (a relatively high threshold). In this embodiment, each intensity threshold equals a decibel value, such as intensity values of −130 dB, −100 dB, −80 dB, −60 dB, etc. As described below, each intensity threshold serves as an intensity boundary or intensity line that, if exceeded, triggers intensity reduction.

The harmonic class section 248 displays a plurality of harmonic class indicators 258. In the example shown, each of the harmonic class indicators 258 is represented by a unique symbol. The symbols in this example are integers (e.g., whole numerals) that correspond to the harmonic series described above. Referring to FIGS. 6 and 12, the numeral 1 in FIG. 12 corresponds to the fundamental (first harmonic), the numeral 2 in FIG. 12 corresponds to the second harmonic, the numeral 4 in FIG. 12 corresponds to the fourth harmonic, etc. The intensity regulation system 210 enables the user to select or otherwise activate a desired one of the harmonic class indicators 258. In response, the intensity regulation system 210 selects or otherwise designates the harmonic class corresponding to the selected harmonic class indicator 258. As described below, the intensity regulation system 210 is operable to track (and programmatically latch onto) the designated harmonic class for the intensity regulation functionality of the intensity regulation system 210.

In an embodiment, to implement the intensity regulation system 210 for operation with DAW 212, the user must insert the intensity regulation system 210 on a desired one of the sound tracks 231. DAW 212 displays an insert symbol that enables the user to perform that insertion. Once inserted on the sound track, the signal from the audio file passes through the system logic 226. The audio the user hears is the version of audio that has been altered by the intensity regulation system 210, unless the intensity regulation system 210 is in bypass mode, wherein the unaffected audio signal is heard.

In an embodiment, the system logic 226 is configured to cause graphical output representing one or more frequency analyzers, graphs, gain reduction meters, and other visual indicators.

When analyzing any of the sound tracks 231, the user can provide desired inputs into the system interface 240, as described above. The intensity regulation system 210 stores the inputs as settings usable for the future. In one example, inserts the intensity regulation system 210 on the sound track 232. Next, the user provides a first set of inputs into the system interface 240 for the sound track 232, and the user provides a second set of inputs into the system interface 240 for the sound track 234. The setting section 250 displays a list of setting identifiers 260. In this example, the first setting identifier 262 corresponds to the settings associated with the first set of inputs for the sound track 232. The second setting identifier 264 corresponds to the settings associated with the second set of inputs for the sound track 234.

With continued reference to FIG. 12, the control elements 252 are selectable to change user preferences, edit the settings, and perform other functions. The mode control element 254 is selectable to change the modes of the intensity regulation system 210. In an embodiment, the intensity regulation system 210 has an on mode, an off mode and a smart mode. In the on mode, the intensity regulation system 210 implements the intensity regulation for the applicable sound asset, as described below. In the off mode, the intensity regulation system 210 is disabled or deactivated.

In the smart mode, the intensity regulation system 210 remains activated but suspends any intensity reduction until the intensity regulation system 210 detects a trigger, such as a designated, sonic event or sonic pattern. When the trigger occurs, the intensity regulation system 210 implements the intensity regulation for the applicable sound asset. In an embodiment, the system logic 226 includes artificial intelligence to control and manage the implementation of the intensity regulation.

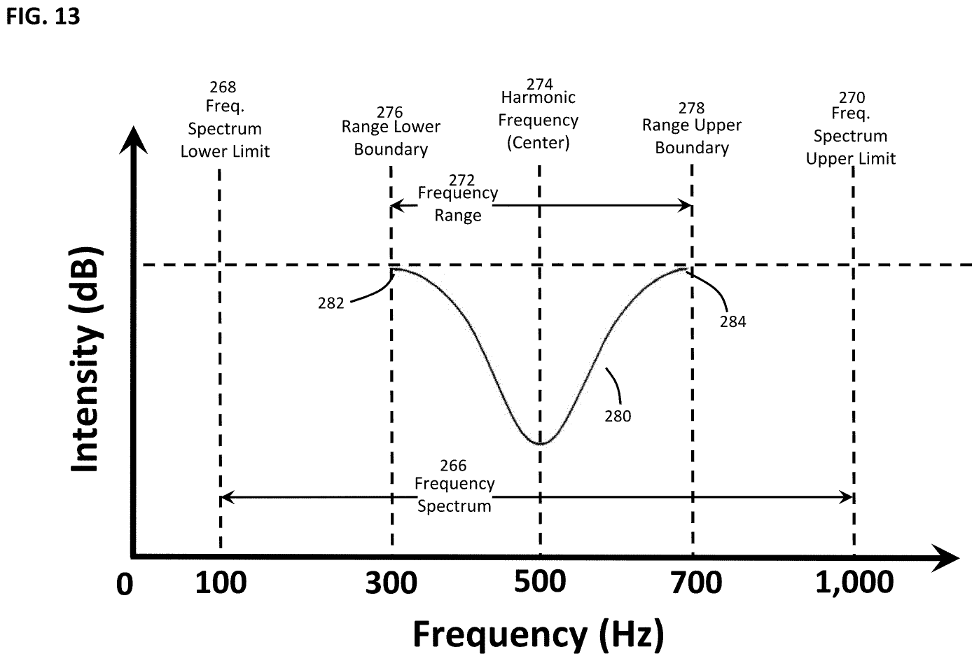

DAW 212 enables the user to select one of the sound tracks 231 as described above. As shown in FIG. 13, a frequency spectrum 266 (the graph of which is not shown) of one of the sound tracks 231 starts at a spectrum lower limit 268 (100 Hz) and continuously extends to a spectrum upper limit 270 (1,000 Hz). In the example shown, such frequency spectrum 266 has a bandwidth of 900 Hz (the difference between 1,000 Hz and 100 Hz).

In this example, the user provided inputs into the frequency range section 242, resulting in a setting of the frequency range 272. Frequency range 272 has a range bandwidth of 400 Hz (700 Hz-300 Hz). The frequency range 272 is associated with the desired harmonic class selected by the user through inputs into the harmonic class section 248. Referring to FIG. 13, each harmonic class (including the selected one) has a harmonic frequency 274 that is based on the rank or order of the harmonic class. As described above, this harmonic frequency 274 will vary or shift based on changes in the fundamental frequency associated with the harmonic frequency. Therefore, the selected harmonic class can laterally vary or shift within the frequency spectrum 266 while the associated sound asset is performed or played. During this process, the intensity regulation system 210 causes the frequency range 272 to dynamically track or follow the shifting harmonic class.

At the point in time of the frequency spectrum 266 shown in FIG. 13, the fundamental frequency is 100 Hz, and, in this example, the user used the harmonic class section 248 to select the fifth harmonic. At this point in time, the harmonic frequency 274 for the fifth harmonic is 500 Hz (based on 5×100 Hz=500 Hz). Also, at this point in time, the frequency range 272 has a range lower boundary 276 at 300 Hz and a range upper boundary 278 at 700 Hz. The frequency range 272, having a bandwidth of 400 Hz bounds or surrounds the harmonic frequency 274 so that half of the bandwidth is lower than the harmonic frequency 274 and half of the bandwidth is higher than the harmonic frequency 274. In alternate embodiments, the frequency range 272 can asymmetrically surround the harmonic frequency 274, having, for example, one-third of its bandwidth lower than the harmonic frequency 274 and two-thirds of its bandwidth higher than the harmonic frequency 274.

When the intensity regulation system 210 is operated to regulate intensity, as described below, the frequency range 272 tracks and bounds the harmonic frequency 274 (as the harmonic frequency 274 varies) and simultaneously bounds other frequencies within the frequency spectrum 266 that are adjacent to the variable harmonic frequency 274. Put another way, the frequency range 272 operatively or programmatically latches onto or couples to the variable harmonic frequency 274.

In an embodiment, the system logic 226 specifies or generates a parabolic function corresponding to an intensity reduction smoother. As shown in FIG. 13, the intensity reduction smoother is represented by a parabolic smoothing curve 280. The intensity reduction smoother is associated with the frequency range 272, having a lower end 282 at the range lower boundary 276 and an upper end 284 at the range upper boundary 278. The intensity regulation system 210 parabolically reduces intensity in accordance with the smoothing curve 280. As described below, this provides for gradual intensity reduction along the modified segment of the frequency spectrum 266, reducing abrupt intensity drops for enhanced sound quality.

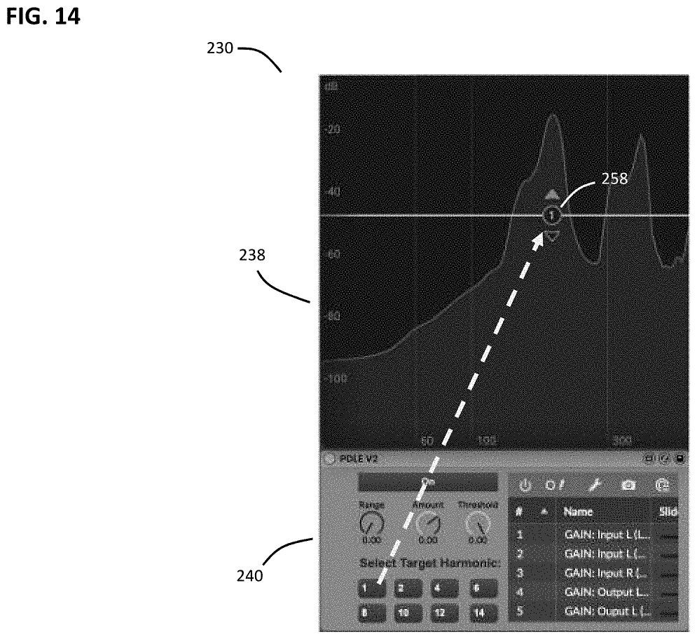

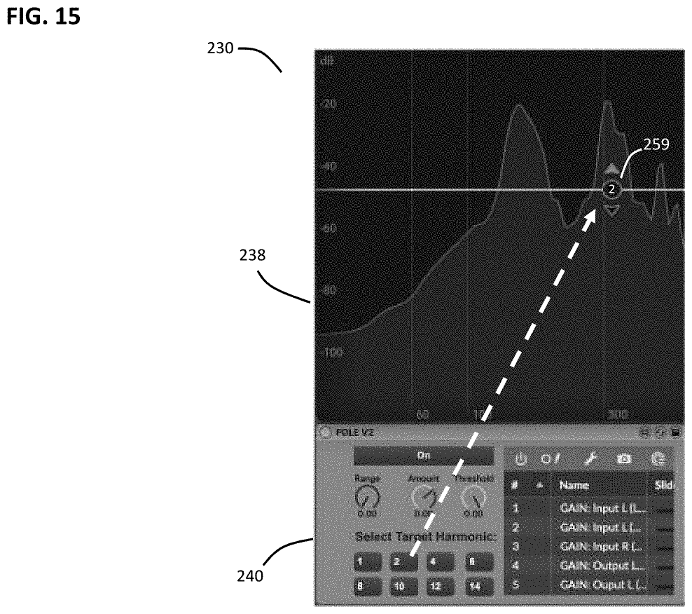

Referring to FIG. 14, in one example of harmonic class selection using the system interface 240, the user selected the first harmonic (fundamental frequency), which the intensity regulation system 210 will track. As shown, the intensity regulation system 210 causes a graphical display of the harmonic class indicator 258, in this example, the encircled numeral one. Referring to FIG. 15, in another example of harmonic class selection using the system interface 240, the user selected the second harmonic, which the intensity regulation system 210 will track. As shown, the intensity regulation system 210 causes a graphical display of the harmonic class indicator 259, in this example, the encircled numeral two.

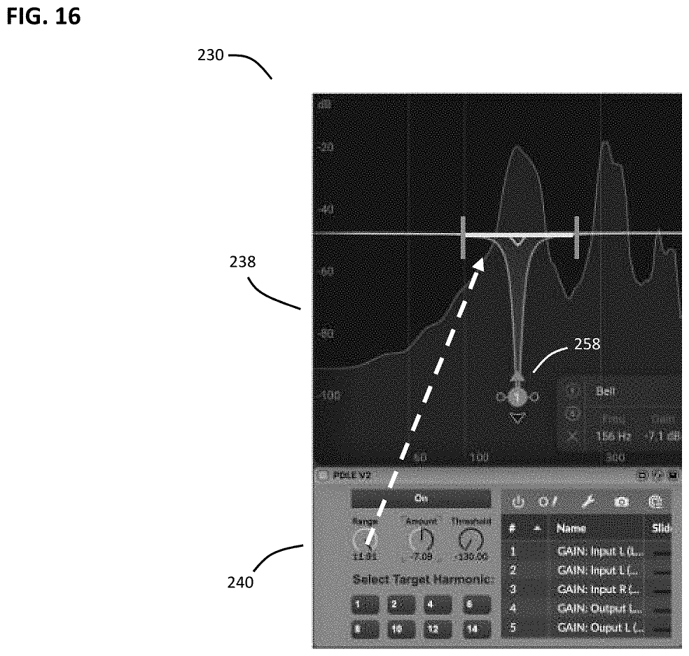

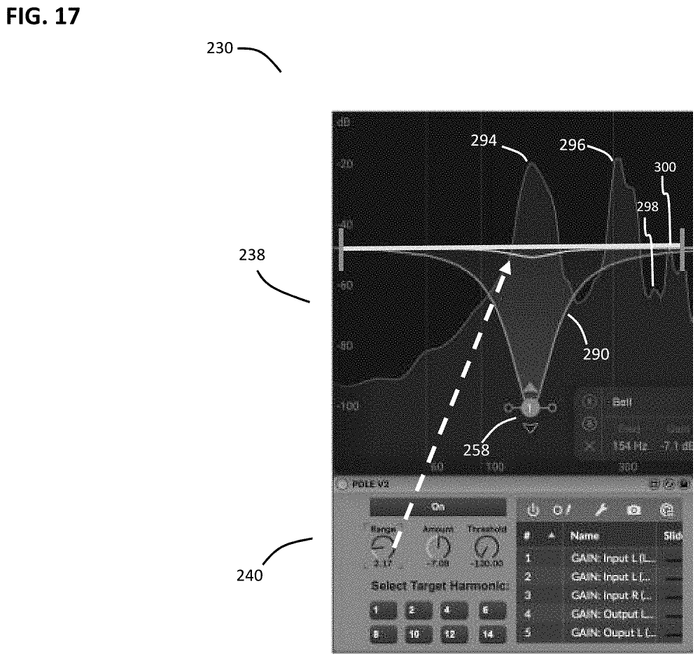

Referring to FIG. 16, in one example of the user's setting of a desired frequency range 272, through use of the frequency range section 242, the user specified a relatively small range bandwidth. Referring to FIG. 17, in another example of the user's setting of a desired frequency range 272, through use of the frequency range section 242, the user specified a relatively large range bandwidth. Depending on the embodiment, the intensity regulation system 210 can cause graphical displays of the boundaries of the frequency ranges.

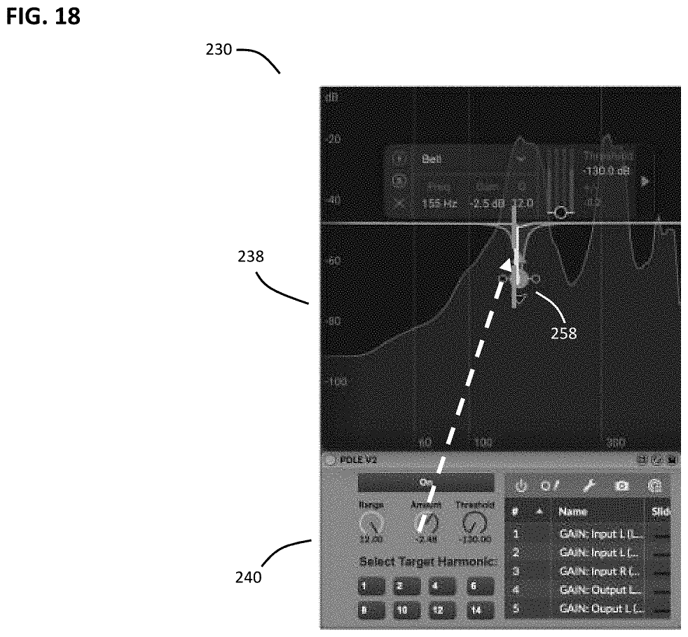

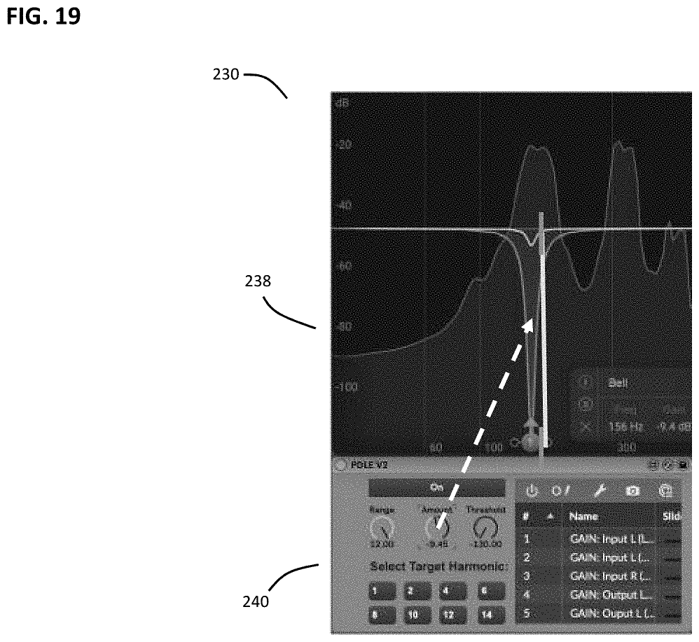

Referring to FIG. 18, in one example of the user's setting of a desired intensity reduction amount, through use of the reduction amount section 244, the user specified a relatively small intensity reduction amount. Referring to FIG. 19, in another example of the user's setting of a desired intensity reduction amount, through use of the reduction amount section 244, the user specified a relatively large intensity reduction amount.

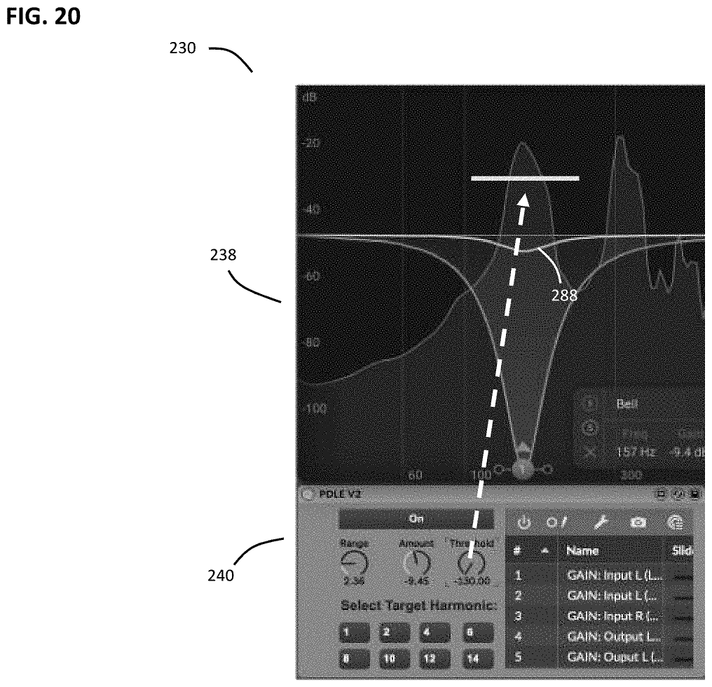

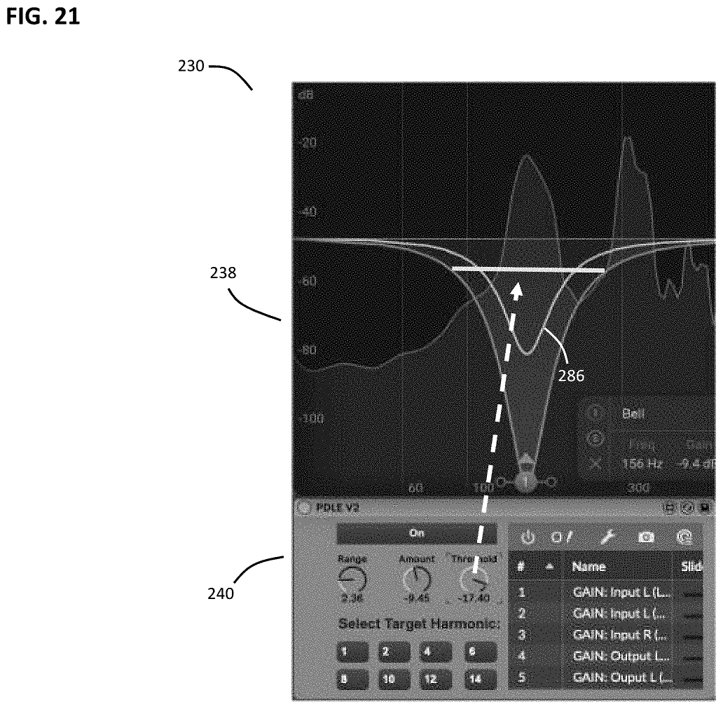

Referring to FIG. 20, in one example of the user's setting of a desired intensity threshold, through use of the threshold section 246, the user specified a relatively high intensity threshold. Referring to FIG. 21, in another example of the user's setting of a desired intensity threshold, through use of the threshold section 246, the user specified a relatively low intensity threshold. Accordingly, the reduction line 286 (shown in FIG. 21) dips downward substantially more than the reduction line 288 (shown in FIG. 20).

Referring back to FIG. 17, the smoothing curve 290 graphically represents the intensity reduction smoother, which is associated with the frequency range 292. The frequency range 292 has a range bandwidth great enough to bound or surround the first harmonic 294 (the fundamental) and a plurality of other frequencies 296, 298 and 300. In an embodiment, depending on whether the intensities of the first harmonic 294 and other frequencies 296, 298, 300 exceed the intensity threshold (as described below), the intensity regulation system 210 will reduce the intensities of the first harmonic 294 and the other frequencies 296, 298 and 300. In the event of reduction, the intensity regulation system 210 will apply the full extent of the reduction amount at the center of the smoothing curve 290 and taper the reduction amount, gradually lowering the level of reduction along the curved halves of the smoothing curve 290. As described above, this provides for smoother sound transitions that result from the intensity cutting of the intensity regulation system 210.

Referring back to FIGS. 9-10, in an embodiment, the system module 220 includes logic, data or a combination thereof that define, specify or otherwise provide a regulation condition. The regulation condition includes a plurality of requirements, including a first requirement to be within the frequency range 272. This first requirement can be considered the first prong of the regulation condition. The regulation condition also includes a second requirement to exceed the intensity threshold. This second requirement can be considered the second prong of the regulation condition. To satisfy the regulation condition, one or more frequencies of a frequency spectrum must be within the bounds of the frequency range 272 and must also exceed the intensity threshold. Accordingly, in this embodiment, the regulation condition is a multi-prong condition that is not satisfied if only one of the first and second conditions is met. It should be appreciated that the second requirement of the regulation condition includes or specifies a designated relationship between the one or more frequencies and the intensity threshold. Here, the designated relationship is formed or reached when the one or more frequencies become greater than the intensity threshold.

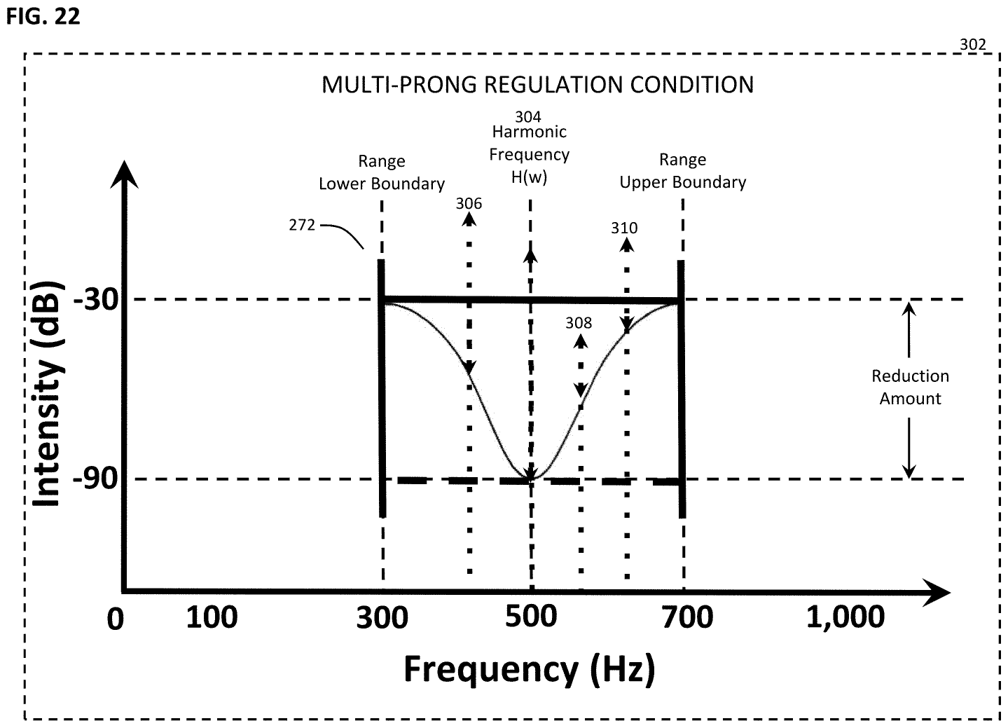

Referring to FIGS. 12 and 22, in the example shown in FIG. 22, the user provided an input into the harmonic class section 248 to select a harmonic class, such as H1, H2, H4, etc. In the example shown, the w in H(w) indicates any desired integer. Next, in this example, the user: (a) provided an input into the frequency range section 242 to set a range bandwidth of 400 Hz for the frequency range 272, (b) provided an input into the threshold section 246 to set an intensity threshold of a value of −30 db, (c) provided an input into the reduction amount section 244 to set a reduction amount of a value of 60 dB (the difference between −30 dB and −90 dB). In this example, the frequency range 272 is dimensioned or sized to bound or surround the following: (a) the harmonic frequency 304 of the harmonic series of the selected harmonic class; (b) an adjacent, nearby, neighboring or ancillary frequency 306; (c) an adjacent, nearby, neighboring or ancillary frequency 308; and (d) an adjacent, nearby, neighboring or ancillary frequency 310. The multi-prong regulation condition 302 is setup or configured with the settings based on these inputs by the user. In particular, the first prong of the regulation condition 302 requires the tracked frequencies to fall within the frequency range 272, and the second prong of the regulation condition 302 requires the tracked frequencies to reach a designated relationship with the threshold value of −30 db, that is, the tracked frequencies must be greater than that threshold value.

In operation of the intensity regulation by the intensity regulation system 210, the intensity regulation system 210 implements or applies the regulation condition 302 to the selected frequency spectrum of the desired sound asset. As shown in FIG. 22, the intensity regulation system 210 programmatically couples, links or latches the frequency range 272 to the selected harmonic class so that the frequency range 272 tracks or follows the selected harmonic class as the harmonic frequency of the class varies over time (e.g., shifts) during the playback or processing of the frequency spectrum. In this example, at a single point in time, the intensity regulation system 210, executing the regulation condition 302, detects at least one frequency that both exceeds the −30 dB threshold (which achieves the designated relationship with the threshold) and is within the frequency range 272 which, in this example, spans from 300 Hz to 700 Hz. In this example, the harmonic frequency 304 and the ancillary frequencies 306 and 310 each satisfy the first prong of the regulation condition 302. However, the frequency 308 does not satisfy the second prong of the regulation condition 302 because the intensity of ancillary frequency 308 does not exceed the −30 dB threshold, that is, the designated relationship is not reached.

In one embodiment, once any frequency satisfies the regulation condition 302, the intensity regulation system 210 performs the attenuation or intensity regulation function described above. In another embodiment, multiple frequencies satisfy the regulation condition 302, the intensity regulation system 210 performs the attenuation or intensity regulation function described above.

In one embodiment, if the regulation condition 302 is satisfied, the intensity regulation system 210 performs the attenuation or intensity regulation function on all of the frequencies within the frequency range 292. In such embodiment, the intensity regulation system 210 will reduce or regulate the intensity of the ancillary frequency 308 even though its intensity is less than −30 dB. In another embodiment, if the regulation condition 302 is satisfied, the intensity regulation system 210 performs the attenuation or intensity regulation function only on the frequencies within the frequency range 292 having intensities that exceed the intensity threshold. In such embodiment, the intensity regulation system 210 will not reduce or regulate the intensity of the ancillary frequency 308 because its intensity is less than −30 dB.

In an embodiment, as shown in FIG. 22, when performing the intensity regulation, the intensity regulation system 210: (a) reduces the intensity of the harmonic frequency by the entire magnitude of the reduction amount in accordance with the smoothing curve 290, (b) reduces the intensity of ancillary frequency 306 by a first percentage or portion of the reduction amount in accordance with the smoothing curve 290, (c) reduces the intensity of ancillary frequency 308 by a second percentage or portion of the reduction amount in accordance with the smoothing curve 290, and (d) reduces the intensity of ancillary frequency 310 by a third percentage or portion of the reduction amount in accordance with the smoothing curve 290. As shown, the percentages vary in accordance with the smoothing curve 290.

In one embodiment, the system logic 226 of the intensity regulation has a plurality of computer readable instructions configured to direct the one or more processors 214 to: (a) receive a harmonic class input from a user that corresponds to the user's selection of one of a plurality of different harmonic classes 150, 152, 154, 156, 158 wherein each of the harmonic classes 150 is associated with a variable harmonic frequency; (b) receive from the user, a frequency range input that is associated with the selected harmonic class, wherein the frequency range input specifies a frequency range 272 dimensioned or great enough to bound the variable harmonic frequency of the selected harmonic class and a plurality of other frequencies; (c) receive from the user, an intensity threshold input associated with the selected harmonic class, wherein the intensity threshold input corresponds to an intensity threshold; (d) receive from the user, an intensity reduction input associated with the selected harmonic class, wherein the intensity reduction input corresponds to an intensity reduction amount; (e) detect whether one or more frequencies of a frequency spectrum 266 satisfy the regulation condition described above; and (f) for the frequencies that satisfy the regulation condition, attenuate or reduce their intensities by the intensity reduction amount or a percentage of the intensity reduction amount.

In an embodiment, with respect to any harmonic frequency that satisfies the regulation condition, the instructions are configured to direct the one or more processors 214 to reduce the intensity of the harmonic frequency by the full magnitude of the intensity reduction amount. With respect to any other or ancillary frequencies that satisfy the regulation condition, the instructions are configured to direct the one or more processors 214 to reduce the intensity of the ancillary frequencies by a percentage, fraction or portion of the intensity reduction amount. This partial reduction or partial attention is based on the smoothing curve 290, as described above.

In an embodiment, the frequency spectrum 266 is based on a monophonic sound asset. In yet another embodiment, the reduction occurs before the first time of processing the entire frequency spectrum 266. In an embodiment, each of the variable harmonic frequencies is variable based on a change in a fundamental frequency.

In an embodiment, harmonic frequency and the ancillary frequencies within the frequency range 272 are free of any intensity reduction unless the regulation condition is satisfied. This provides the frequencies with the freedom to rise and fall without being attenuated so long as they do not meet the regulation condition. Unlike audio engineering technology such as equalization, the intensity regulation system 210 regulates the targeted frequencies rather than statically or fixedly attenuating the targeted frequencies. In one embodiment, the intensity regulation system 210 gives each targeted frequency (e.g., the variable harmonic frequency or any other frequency within the frequency range 272) the freedom to vary without being altered as long the intensities of all of the frequencies in the range remain below the intensity threshold. In another embodiment, the intensity regulation system 210 gives each targeted frequency (e.g., the variable harmonic frequency or any other frequency within the frequency range 272) the freedom to vary without being altered as long as the targeted frequency remains below the intensity threshold. Accordingly, the intensity regulation system 210 avoids overly reducing intensities of frequencies within the frequency range, which can impair the quality and color of sound assets.

To use the intensity regulation system 210, as described above, the user first configures or sets-up the intensity regulation system 210. One method of use includes the following steps: (a) recording a performer in a studio using DAW 212, resulting in a data file storing the sound tracks of the resulting sound asset (e.g., Song ABC), such as monophonic vocals stored on a first sound track and monophonic instrumentals stored on a second sound track; (b) after the live recording session, using DAW 212 to select, for example, the first sound track for pitch analysis, identifying quality issues or tonal inconsistencies, such as harmonic intensities or frequencies of concern; and (c) inputting desired parameters and inputs to establish settings through use of the system interface 240, which causes the intensity regulation system 210 to produce an improved, modified version of the first sound track based on the settings.

In another embodiment, the intensity regulation system 210 saves or otherwise stores the settings for future use. For example, the same performer may return to the studio for a repeat, live performance of Song ABC. Before the repeat, live performance begins, the user can: (a) activate or otherwise power-on the intensity regulation system 210 with the stored and activated settings; (b) use DAW 212 to receive the audio signal from the performer's vocals, which are converted to a digital signal, which, in turn, is converted to digital or binary code stored within the one or more data storage devices of DAW 212, such as buffer memory devices; and (c) while the one or more processors 214 are processing the code, interoperating DAW 212 and the intensity regulation system 210 to direct the one or more processors 214 to apply the system logic 226 to the code before the end of the live performance, resulting in a modified version of the first sound track. In such embodiment, the intensity regulation system 210, in cooperation with DAW 212, is configured to perform intensity regulation while the intensity regulation system 210 is processing or reading the code of the sound track along a time axis. In other words, the intensity regulation occurs in real time instead of requiring the user to wait for the data processors 214 to fully process and read the code of the sound track. This provides an important time-saving advantage for users.

In embodiments described above, the intensity regulation system 210 is operable to perform an intensity reduction. It should be understood that an intensity reduction can include an intensity elimination. For example, to achieve an audio muting or mute effect, the intensity regulation system 210 is operable to eliminate intensity.

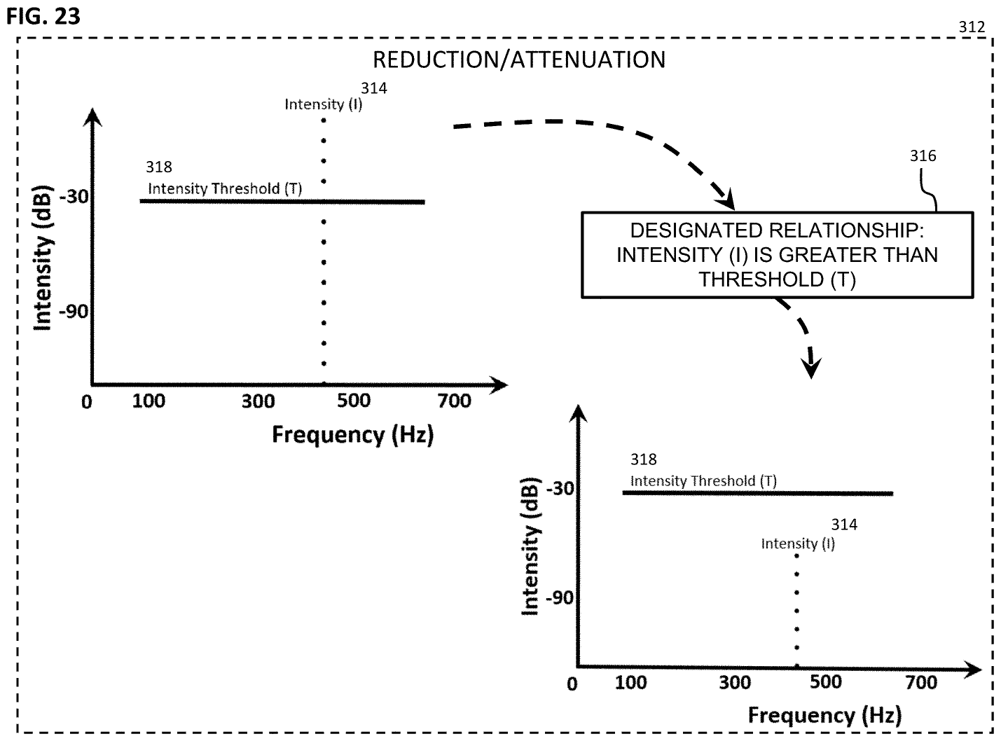

Referring to FIG. 23, in an embodiment, the second prong 312 of the regulation condition 302 includes a requirement that at least one of the tracked frequencies 314 reaches a designated relationship 316 with the intensity threshold (T) 318. In the example shown, the designated relationship 316 occurs, is formed or is otherwise reached when the frequency 314 reaches an intensity (I) that is greater than T. As illustrated, if the first prong and the second prong 312 of the regulation condition 302 are satisfied, the intensity regulation system 210 reduces or attenuates the tracked frequency 314.

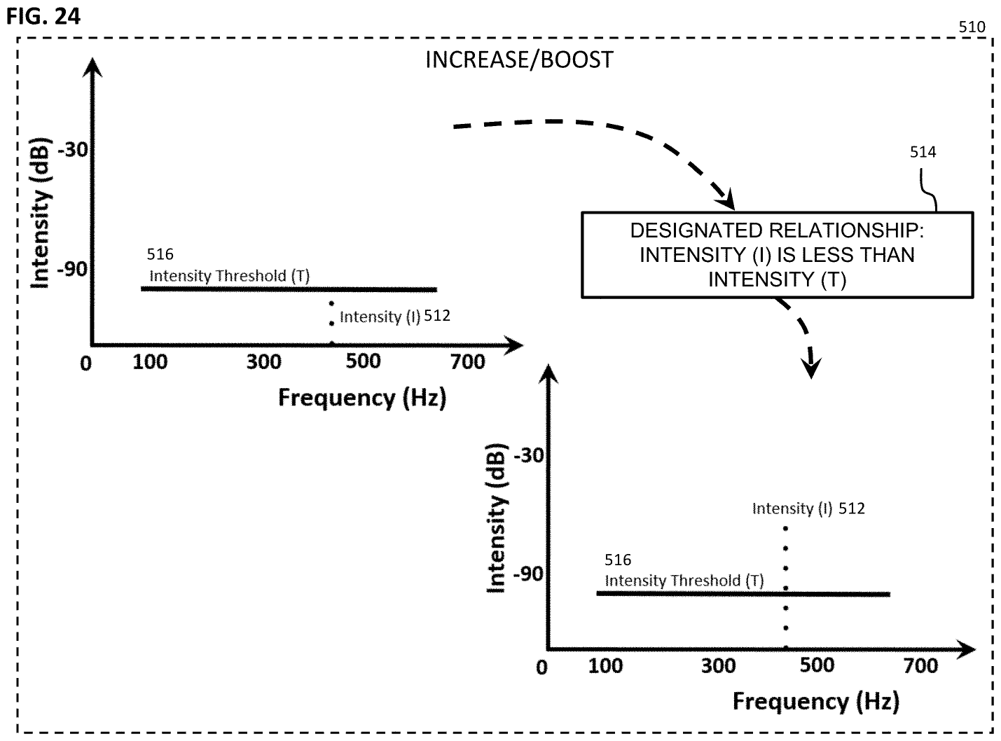

In an embodiment, an alternate intensity regulation system has the same structure, elements and functionality of the intensity regulation system 210 except that the alternate intensity regulation system is structured, configured and operable according to an intensity modification that is reverse of the intensity modification described for the intensity regulation system 210. In particular, the alternate intensity regulation system increases or otherwise boosts intensity instead of decreasing or attenuating intensity. In this regard, (a) the requirement of the regulation condition 302 described in terms of exceeding, being greater than or being higher than an upper limit, is replaced with a requirement described in terms of being less than or being lower than a lower or minimal limit, and (b) the intensity change produced by the intensity regulation system 210 (intensity reduction or attenuation) is replaced with an intensity increase or otherwise an intensity boost. Referring to FIG. 24, the second prong 510 of the regulation condition of this alternative intensity regulation system includes a requirement that at least one of the tracked frequencies 512 reaches a designated relationship 514 with the intensity threshold (T) 516. In the example shown, the designated relationship 514 occurs, is formed or is otherwise reached when the frequency 512 fails to reach an intensity (I) that equal to T or is otherwise less than T. As illustrated, if the first prong and the second prong 510 of such regulation condition are satisfied, the alterative intensity regulation system increases or boosts the tracked frequency 512.

In an embodiment, the intensity regulation system 210 and the alternative intensity regulation system each engages the DAS according to attack and release time periods. Attack is the time it takes for the intensity regulation system to act upon the DAS after detecting that the regulation condition has been met. Release is the time it takes for the intensity regulation system to stop acting on the DAS after the DAS falls outside of the regulation condition.

In an embodiment, the intensity regulation system (whether the intensity regulation system 210 or the alternative intensity regulation system) can separately engage multiple harmonics simultaneously. If the user desires to regulate the intensity of harmonic two and harmonic five, for example, the user may do so, and apply separate settings for the intensity threshold, amount of intensity change, attack, and release. If the user desires to regulate the intensity of three, four, five or more harmonics, all with unique settings, the intensity regulation system 210 enables the user to do so.

The disclosure set forth above describes the operation of the intensity regulation system for purposes of attenuation and boosting, depending on the embodiment. In an embodiment, the intensity regulation system is configured to be operable in a dual operation mode. In this mode, the intensity regulation system will boost or attenuate the frequencies within the selected range of frequencies associated with the selected harmonic class, according to the selected threshold, amount, attack, and release, should the intensity associated with that range of frequencies fall below or raise above the set threshold.

In one example, an engineer is attempting to tame the raspiness/harshness of a vocal performance. However, when the vocalist falls from a higher to a lower register, the engineer notices that the resonant frequency associated with the rasp falls from 5 kHz to 4 kHz. That is because it may be associated with pitch. Hence, the raspy tone cannot be pinpointed to one specific frequency. The typical approaches of the known audio engineering technology use methods that involve (a) cuts that are heavily reductive, resulting in unnaturalness to the sound; (b) changes more frequencies than desirable, causing too noticeable of a change to the frequency spectrum or (c) cuts that remain active throughout the entire performance because the known audio engineering technology lacks the capability to both pitch-track and perform dynamic attenuation. The intensity regulation system 210, as described above, resolves or otherwise reduces all of these shortcomings of the known audio engineering technology.

In an embodiment, intensity regulation system 210 provides the advantage of implementing both pitch-tracking and dynamic attenuation. The intensity regulation system 210 enables the user to pinpoint or select the responsible/matching harmonics. Once selected, the harmonics will be tracked and attenuated as they shift in frequency, at levels determined by a user-defined ratio and threshold. The ratio determines the amount of intensity reduction, and the threshold represents the level that must be surpassed for reduction to happen. The intensity regulation system 210 provides a comprehensive solution to reducing offending resonant frequencies with utmost transparency, maintaining as close to complete integrity of the signal as can be conceived with digital signal processing.

Referring back to FIGS. 9-10, in an embodiment, the system data 208 includes the settings or setting data input by the user through use of the system interface 240, data corresponding to the user preferences set through the system interface 240, data representing the graphics displayed within the system interface 240, and other data generated during operation of the intensity regulation system 210.

In an embodiment, the system logic 226 and system data 208 are configured and structured to be stored in a database. A processor, such as one of the one or more processors 214, can access such database over any suitable type of network, or the processor can access such database directly if the database and processor are parts of a single server unit, including a system server. In addition, network access devices operated by users can access such database over any suitable type of network. Depending upon the embodiment, the network can include one or more of the following: a wired network, a wireless network, a local area network (LAN), an extranet, an intranet, a wide area network (WAN) (including the Internet and the data communication network 222), a virtual private network (VPN), an interconnected data path across which multiple devices may communicate, a peer-to-peer network, a telephone network, portions of a telecommunications network for sending data through a variety of different communication protocols, a Bluetooth® communication network, a radio frequency (RF) data communication network, an infrared (IR) data communication network, a satellite communication network or a cellular communication network for sending and receiving data through short messaging service (SMS), multimedia messaging service (MMS), hypertext transfer protocol (HTTP), direct data connection, Wireless Application Protocol (WAP), email or any other suitable message transfer service or format.

In an embodiment, processors 214 can include a data processor or a central processing unit (CPU). The one or more data storage devices 216 can include a database, a hard drive with a spinning magnetic disk, a Solid-State Drive (SSD), a floppy disk, an optical disk (including a CD or DVD), a Random Access Memory (RAM) device, a Read-Only Memory (ROM) device (including programmable read-only memory (PROM)), electrically erasable programmable read-only memory (EPROM), electrically erasable programmable read-only memory (EEPROM)), a magnetic card, an optical card, a flash memory device (including a USB key with non-volatile memory, any type of media suitable for storing electronic instructions or any other suitable type of computer-readable storage medium.

Users can use or operate any suitable input/output (I/O) device to transmit inputs that are directly or indirectly received by the processors 214, the DAW 212 and the intensity regulation system 210, including a personal computer (PC) (including a desktop PC, a laptop or a tablet), smart television, Internet-enabled TV, person digital assistant, smartphone, cellular phone, a mobile communication device, a smart speaker, an electronic microphone, a virtual reality headset, or an augmented reality headset. In one embodiment, such I/O device has at least one input device (including a touchscreen, a keyboard, a microphone, a sound sensor or a speech recognition device) and at least one output device (including a speaker, a display screen, a monitor or an LCD). In an embodiment, the intensity regulation system 210 includes speech and sound generation logic that, when executed by one or more processors 214, causes such I/O device to generate sounds and audible output that corresponds to (or is a text-to-speech conversion of) the textual, visual and graphical outputs generated by the processors 214 based on the intensity regulation system 210.

In an embodiment, the computer-readable instructions, formulas, algorithms, logic and programmatic structure of the system logic 226 are implemented with any suitable programming or scripting language, including, but not limited to, C, C++, Java, COBOL, assembler, PERL, Visual Basic, SQL Stored Procedures, Extensible Markup Language (XML), Hadoop, “R,” json, mapreduce, python, IBM SPSS, IBM Watson Analytics, IBM Watson and Tradeoff Analytics. The system logic 226 can be implemented with any suitable combination of data structures, objects, processes, routines or other programming elements.

In an embodiment, the interfaces based on the system logic 226 can be Graphical User Interfaces (GUIs) structured based on a suitable programming language. Each GUI can include, in an embodiment, multiple windows, pulldown menus, popup elements, buttons, scroll bars, iconic images, wizards, mouse symbols or pointers, and other suitable graphical elements. In an embodiment, the GUI incorporates multimedia, including sound, voice, motion video and virtual reality interfaces to generate outputs based on the execution of the system logic 226.

In an embodiment, the memory devices and data storage devices described above are non-transitory mediums that store or participate in providing instructions to a processor for execution. Such non-transitory mediums can take different forms, including non-volatile media and volatile media. Non-volatile media can include, for example, optical or magnetic disks, flash drives, and any of the storage devices in any computer. Volatile media can include dynamic memory, such as main memory of a computer. Forms of non-transitory computer-readable media therefore include, for example, a floppy disk, flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, or any other medium from which a computer can read programming code and/or data. Many of these forms of computer readable media may be involved in carrying one or more sequences of one or more instructions to a processor for execution. In contrast with non-transitory mediums, transitory physical transmission media can include coaxial cables, copper wire and fiber optics, including the wires that comprise a bus within a computer system, a carrier wave transporting data or instructions, and cables or links transporting such a carrier wave. Carrier-wave transmission media can take the form of electric or electromagnetic signals, or acoustic or light waves such as those generated during RF and IR data communications.

It should be appreciated that at least some of the subject matter disclosed herein includes or involves a plurality of steps or procedures that specify one or more methods. In an embodiment, some of the steps or procedures occur automatically as controlled by a processor or electrical controller. In another embodiment, some of the steps or procedures occur manually under the control of a human. In yet another embodiment, some of the steps or procedures occur semi-automatically as partially controlled by a processor or electrical controller and as partially controlled by a human.

As will be appreciated, aspects of the disclosed subject matter may be embodied as a system, method, or computer program product. Accordingly, aspects of the disclosed subject matter may take the form of an entirely hardware embodiment, an entirely software embodiment (including firmware, resident software, micro-code, etc.), or an embodiment combining software and hardware aspects that may all generally be referred to herein as a “service,” “circuit,” “circuitry,” “module,” and/or “system.” Furthermore, aspects of the disclosed subject matter may take the form of a computer program product embodied in one or more computer readable mediums having computer readable program code embodied thereon.

Aspects of the disclosed subject matter are described herein in terms of steps and functions with reference to flowchart illustrations and block diagrams of methods, apparatuses, systems and computer program products. It should be understood that each such step, function block of the flowchart illustrations and block diagrams, and combinations thereof, can be implemented by computer program instructions. These computer program instructions may be provided to a processor of any suitable computer or programmable data processing apparatus to produce a machine, such that the instructions, which execute via the processor of the computer or other programmable data processing apparatus, create results and output for implementing the functions described herein.

These computer program instructions may also be stored in a computer readable medium that can direct a computer, other programmable data processing apparatus, or other devices to function in a particular manner, such that the instructions stored in the computer readable medium produce an article of manufacture including instructions which implement the functions described herein.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions described herein.

Additional embodiments include any one of the embodiments described above, where one or more of its components, functionalities or structures is interchanged with, replaced by or augmented by one or more of the components, functionalities or structures of a different embodiment described above.

It should be understood that various changes and modifications to the embodiments described herein will be apparent to those skilled in the art. Such changes and modifications can be made without departing from the spirit and scope of the present disclosure and without diminishing its intended advantages. It is therefore intended that such changes and modifications be covered by the appended claims.

Although several embodiments of the disclosure have been disclosed in the foregoing specification, it is understood by those skilled in the art that many modifications and other embodiments of the disclosure will come to mind to which the disclosure pertains, having the benefit of the teaching presented in the foregoing description and associated drawings. It is thus understood that the disclosure is not limited to the specific embodiments disclosed herein above, and that many modifications and other embodiments are intended to be included within the scope of the appended claims. Moreover, although specific terms are employed herein, as well as in the claims which follow, they are used only in a generic and descriptive sense, and not for the purposes of limiting the present disclosure, nor the claims which follow.

The following is claimed:

1. An intensity regulation system comprising:
one or more data storage devices comprising a plurality of computer readable instructions configured to direct one or more processors to:
receive a harmonic class input corresponding to a selection of one of a plurality of different harmonic classes, wherein each of the harmonic classes is associated with a variable harmonic frequency;
receive a frequency range input associated with the selected harmonic class, wherein the frequency range input specifies a frequency range great enough to bound the variable harmonic frequency of the selected harmonic class and a plurality of other frequencies;
receive an intensity threshold input associated with the selected harmonic class, wherein the intensity threshold input corresponds to an intensity threshold;
receive an intensity change input associated with the selected harmonic class, wherein the intensity change input corresponds to an amount of an intensity change, wherein the intensity change comprises one of an intensity reduction, an intensity elimination, or an intensity increase;
detect whether one or more frequencies of a frequency spectrum satisfy a regulation condition, wherein the regulation condition comprises:
a first requirement for the one or more frequencies to be within the frequency range; and
a second requirement for the one or more frequencies to comprise a designated relationship to the intensity threshold; and
change an intensity of the detected one or more frequencies by at least part of the amount,
wherein the frequency spectrum is based on a monophonic sound asset,
wherein the intensity change occurs before reaching an end of the frequency spectrum,
wherein each of the variable harmonic frequencies is variable based on a change in a fundamental frequency,
wherein the harmonic frequency and the other frequencies within the frequency range are unmodified by any change in intensity unless the regulation condition is satisfied.

2. The intensity regulation system of claim 1, wherein:
the designated relationship comprises the one or more frequencies being greater than the intensity threshold; and
the intensity change comprises an intensity reduction.

3. The intensity regulation system of claim 1, wherein:
the designated relationship comprises the one or more frequencies being greater than the intensity threshold; and
the intensity change comprises an intensity elimination that is associated with a mute effect.

4. The intensity regulation system of claim 1, wherein:
the designated relationship comprises the one or more frequencies being less than the intensity threshold; and
the intensity change comprises an intensity increase.

5. The intensity regulation system of claim 1, wherein, the intensity change is operable during a performance session while a performer generates the monophonic sound asset.

6. The intensity regulation system of claim 1, wherein the monophonic sound asset is at least partially modified as a result of the intensity change.

7. The intensity regulation system of claim 1, wherein the frequency spectrum is based on a monophonic audio signal related to the monophonic sound asset.

8. One or more data storage devices comprising a plurality of computer readable instructions configured to direct one or more processors to:
receive one or more inputs, wherein the one or more inputs correspond to:
a selection of one of a plurality of different harmonic classes, wherein each of the harmonic classes is associated with a variable harmonic frequency;
a frequency range great enough to bound the variable harmonic frequency of the selected harmonic class and a plurality of other frequencies;
an intensity threshold; and
an amount of an intensity change;
detect whether one or more frequencies of a frequency spectrum satisfy a regulation condition, wherein the regulation condition comprises:
a first requirement to be within the frequency range; and
a second requirement to comprise a designated relationship with the intensity threshold; and
change an intensity of the detected one or more frequencies by at least part of the amount.

9. The one or more data storage devices of claim 8, wherein:
the designated relationship comprises the one or more frequencies being above the intensity threshold; and
the intensity change comprises one of an intensity reduction or an intensity elimination.

10. The one or more data storage devices of claim 8, wherein
the designated relationship comprises the one or more frequencies being below the intensity threshold; and
the intensity change comprises an intensity increase.

11. The one or more data storage devices of claim 8, wherein the frequency spectrum is associated with a monophonic audio signal related to a sound asset.

12. The one or more data storage devices of claim 8, wherein each of the variable harmonic frequencies is variable due to a change in a fundamental frequency caused by variation in the sound asset.

13. The one or more data storage devices of claim 8, wherein the harmonic frequency and the other frequencies within the frequency range are free of any change in intensity unless the regulation condition is satisfied.

14. The one or more data storage devices of claim 8, wherein the intensity change occurs before reaching an end of the frequency spectrum.

15. A method for configuring an intensity regulation system, the method comprising:
configuring a plurality of computer readable instructions to direct one or more processors to:
receive one or more inputs, wherein the one or more inputs correspond to:
a selection of one of a plurality of different harmonic classes, wherein each of the harmonic classes is associated with a variable harmonic frequency;
a frequency range great enough to bound the variable harmonic frequency of the selected harmonic class and a plurality of other frequencies;
an intensity threshold; and
an amount of intensity change;
detect whether one or more frequencies of a frequency spectrum satisfy a regulation condition, wherein the regulation condition comprises:
a first requirement for the one or more frequencies to be within the frequency range; and
a second requirement for the one or more frequencies to comprise a designated relationship with the intensity threshold; and
change an intensity of the detected one or more frequencies by at least part of the amount.

16. The method of claim 15, wherein the intensity change comprises one of:
an intensity reduction;
an intensity elimination, wherein the intensity elimination is associated with a mute effect; or
an intensity increase.

17. The method of claim 15, wherein the frequency spectrum is associated with a monophonic audio signal related to a sound asset.

18. The method of claim 17, wherein the harmonic frequency and the other frequencies within the frequency range are free of any intensity reduction unless the regulation condition is satisfied.

19. The method of claim 18, wherein each of the variable harmonic frequencies is variable due to a change in a fundamental frequency based on change in the sound asset.

20. The method of claim 15, wherein the frequency spectrum is associated with a monophonic audio signal related to a sound asset, the method comprising:
configuring the computer readable instructions to direct the one or more processors to programmatically track the selected harmonic class while the one or more processors process the monophonic audio signal,
wherein, during the tracking, the variable harmonic frequency is variable due to a change in a fundamental frequency caused by variation in a sound asset related to the monophonic audio signal.
